(19) United States
(12) Patent Application Publication
(10) Pub. No.: US 2023/0145693 A1
(43) Pub. Date: May 11, 2023

(54) ENERGY STORAGE SYSTEM

(71) Applicant: LG ELECTRONICS INC., Seoul (KR)

(72) Inventors: Changyong JU, Seoul (KR); Sungeun BANG, Seoul (KR)

(73) Assignee: LG ELECTRONICS INC., Seoul (KR)

(21) Appl. No.: 17/555,223

(22) Filed: Dec. 17, 2021

(30) Foreign Application Priority Data
Nov. 9, 2021 (KR) 10-2021-0153226

(51) Int. Cl. G01R 31/392; H01M 10/44; G01R 31/3842; H01M 10/42

(52) U.S. Cl. CPC G01R 31/392; H01M 10/443; G01R 31/3842; H01M 10/425; H01M 2010/4271

(57) ABSTRACT

The energy storage system of the present disclosure includes: a battery configured to store a received electrical energy in a form of direct current or to output the stored electrical energy; and a battery management system configured to control the battery, wherein the battery management system includes: a sensing unit comprising a plurality of sensors for measuring voltage, current, and temperature of the battery; a memory configured to store a charge/discharge cycle count that is increased according to execution of charge/discharge cycle and a under voltage protection level which is a reference value of a under voltage protection that protects from discharging at a certain voltage or lower; and a microcomputer unit that increases the under voltage protection level, when the charge/discharge cycle count reaches a reference number of times.

### CROSS-REFERENCE TO RELATED APPLICATION

Pursuant to 35 U.S.C. § 119(a), this application claims the benefit of earlier filing date and right of priority to Korean Patent Application No. 10-2021-0153226, filed on Nov. 9, 2021, the contents of which are hereby incorporated by reference herein in its entirety.

### BACKGROUND OF THE INVENTION

### 1. Field of the Invention

The present disclosure relates to an energy storage system, and more particularly, to a battery-based energy storage system and an operating method thereof.

### 2. Description of the Related Art

An energy storage system is a system that stores or charges external power, and outputs or discharges stored power to the outside. To this end, the energy storage system includes a battery, and a power conditioning system is used for supplying power to the battery or outputting power from the battery. A battery management system may manage the battery based on a battery cell, voltage and current of the entire battery, and the like. In addition, the battery management system may calculate a state of health (SOH) and a state of charge (SOC) of the battery, and manage the battery.

The capacity of battery may decrease due to an increase in internal resistance while performing charging/discharging. Battery life is shortened as the number of charge/discharge charge/discharge cycles increases. The state of health (SOH) of battery is called as a remaining life or a health state, and indicates the remaining life or deterioration degree of the battery due to an elapse of time. If the SOH is estimated incorrectly, a safety accident may occur due to over-charging or over-discharging of the battery. Therefore, the SOH of the battery is one of the important parameters for controlling the charge/discharge of the battery and securing reliability.

The SOH is usually expressed as a percentage, and indicates a capacity at the time of use compared to an ideal initial capacity. Here, the capacity at the time of use may be a total capacity that can be used at a corresponding time.

The SOH is estimated by various methods such as a method using an internal resistance, a method using a SOC variation, and a coulomb counting method. For example, Korean Patent Publication No. 10-2016-0119556 corrects an offset error of a current sensor by calculating an SOC variation and filtering the calculated SOH in order to improve accuracy and reliability of SOH estimation.

### SUMMARY OF THE INVENTION

The present disclosure has been made in view of the above problems, and an object of the present disclosure is to provide an energy storage system that can extend a battery life through a control reflecting changes according to the lapse of use time.

Another object of the present disclosure is to provide an energy storage system that can extend a battery usage period while ensuring battery stability.

According to at least one of embodiments of the present disclosure, an energy storage system that can effectively manage data is provided.

In order to achieve the above object, the energy storage system according to embodiments of the present disclosure may increase a battery life and secure a safety by changing a main control factor according to a battery usage time.

In order to achieve the above object, the energy storage system according to embodiments of the present disclosure may secure the safety of the battery by changing the main control factor according to the battery usage time.

In order to achieve the above object, the energy storage system according to embodiments of the present disclosure may include: a battery configured to store a received electrical energy in a form of direct current or to output the stored electrical energy; and a battery management system configured to control the battery, wherein the battery management system includes: a sensing unit comprising a plurality of sensors for measuring voltage, current, and temperature of the battery; a memory configured to store a charge/discharge cycle count that is increased according to execution of charge/discharge cycle and a under voltage protection level which is a reference value of a under voltage protection that protects from discharging at a certain voltage or lower; and a microcomputer unit that increases the under voltage protection level, when the charge/discharge cycle count reaches a reference number of times.

When the charge/discharge cycle count reaches the reference number of times, the microcomputer unit decreases a state of health (SOH) of the battery and store in the memory, and increases the under voltage protection level to correspond to the decrease in the SOH.

The microcomputer unit increases the state of charge (SOC) of the battery to correspond to the decrease in the SOH and store in the memory.

An amount of increase of the SOC is proportional to an amount of increase of the under voltage protection level.

The microcomputer unit updates a power table including C-rate (charging rate) values corresponding to a temperature of the battery and the SOC of the battery and stores the updated power table in the memory.

The microcomputer unit decreases the C-rate values.

The microcomputer unit increases SOC values included in the power table.

The charge/discharge cycle count is increased based on the number of times of discharge.

When the charge/discharge cycle count reaches the reference number of times, the microcomputer unit decreases C-rate values in a power table including the C-rate values corresponding to the temperature of the battery and a SOC of the battery and stores the decreased C-rate values in the memory.

When power is applied, the microcomputer unit reads the charge/discharge cycle count from the memory.

When the charge/discharge cycle is executed, the microcomputer unit increases the charge/discharge cycle count and store in the memory.

When the power is turned off, the microcomputer unit stores a current charge/discharge cycle count in the memory.

A plurality of the reference number of times are set, and the microcomputer unit increases the under voltage protection level, whenever the charge/discharge cycle count reaches each reference number of times.

In order to achieve the above object, the energy storage system according to embodiments of the present disclosure may include: a battery configured to store a received electrical energy in a form of direct current or to output the stored electrical energy; and a battery management system configured to control the battery, wherein the battery management system includes: a sensing unit comprising a plurality of sensors for measuring voltage, current, and temperature of the battery; a memory configured to store a charge/discharge cycle count that is increased according to execution of charge/discharge cycle, and a power table including C-rate values corresponding to temperature of the battery and a state of charge (SOC) of the battery; and a microcomputer unit configured to decrease the C-rate values and store the decreased C-rate values in the memory, when the charge/discharge cycle count reaches a reference number of times.

When the charge/discharge cycle count reaches the reference number of times, the microcomputer unit decreases a state of health (SOH) of the battery and stores in the memory.

The microcomputer unit increases the state of charge (SOC) of the battery to correspond to the decrease in the SOH and stores in the memory.

When the charge/discharge cycle count reaches a reference number of times, the microcomputer unit increases a under voltage protection level.

When the charge/discharge cycle count reaches the reference number of times, the microcomputer unit decreases a state of health (SOH) of the battery and store in the memory, and increases the under voltage protection level to correspond to the decrease in the SOH.

In order to achieve the above object, the energy storage system according to embodiments of the present disclosure may include: a battery configured to store a received electrical energy in a form of direct current, or to output the stored electrical energy; and a battery management system configured to control the battery, wherein the battery management system includes: a sensing unit comprising a plurality of sensors for measuring voltage, current, and temperature of the battery; a memory configured to store a state of charge (SOC) of the battery, a state of health (SOH) of the battery, a charge/discharge cycle count that is increased according to execution of charge/discharge cycle, a under voltage protection level which is a reference value of a under voltage protection that protects from discharging at a certain voltage or lower, and a power table including C-rate values corresponding to temperature of the battery and the state of charge (SOC) of the battery; and a microcomputer unit configured to decrease the state of charge (SOC) of the battery, when the charge/discharge cycle count reaches a reference number of times.

The microcomputer unit updates the SOC of the battery, the under voltage protection level, and the power table according to the decrease of the SOH.

### BRIEF DESCRIPTION OF THE DRAWINGS

The above and other objects, features and advantages of the present disclosure will be more apparent from the following detailed description in conjunction with the accompanying drawings, in which:

FIGS. 1A and 1B are conceptual diagrams of an energy supply system including an energy storage system according to an embodiment of the present disclosure;

FIG. 2 is a conceptual diagram of a home energy service system including an energy storage system according to an embodiment of the present disclosure;

FIGS. 3A and 3B are diagrams illustrating an energy storage system installation type according to an embodiment of the present disclosure;

FIG. 4 is a conceptual diagram of a home energy service system including an energy storage system according to an embodiment of the present disclosure;

FIG. 5 is an exploded perspective view of an energy storage system including a plurality of battery packs according to an embodiment of the present disclosure;

FIG. 6 is a front view of an energy storage system in a state in which a door is removed;

FIG. 7 is a cross-sectional view of one side of FIG. 6;

FIG. 8 is a perspective view of a battery pack according to an embodiment of the present disclosure;

FIG. 9 is an exploded view of a battery pack according to an embodiment of the present disclosure;

FIG. 10 is a perspective view of a battery module according to an embodiment of the present disclosure;

FIG. 11 is an exploded view of a battery module according to an embodiment of the present disclosure;

FIG. 12 is a front view of a battery module according to an embodiment of the present disclosure;

FIG. 13 is an exploded perspective view of a battery module and a sensing substrate according to an embodiment of the present disclosure;

FIG. 14 is a perspective of a battery module and a battery pack circuit substrate according to an embodiment of the present disclosure;

FIG. 15A is one side view in a coupled state of FIG. 14;

FIG. 15B is the other side view in a coupled state of FIG. 14;

FIG. 16 is a diagram for explaining a connection between the battery pack and a battery management system according to an embodiment of the present disclosure;

FIG. 17 is a cross-sectional view of a battery pack according to an embodiment of the present disclosure;

FIG. 18 is a cross-sectional view for explaining a disposition of battery cells inside a battery pack;

FIG. 19 is a perspective view of a thermistor according to an embodiment of the present disclosure;

FIG. 20 is a block diagram of an energy storage system according to an embodiment of the present disclosure;

FIGS. 21 and 22 are diagrams for explaining a battery state according to a lapse of use time;

FIG. 23 is a state transition diagram of an energy storage system according to an embodiment of the present disclosure;

FIG. 24 is a flowchart illustrating a method of operating an energy storage system according to an embodiment of the present disclosure;

FIG. 25 is a graph illustrating changes in SOH according to the lapse of battery use time;

FIG. 26 is a flowchart illustrating a method of operating an energy storage system according to an embodiment of the present disclosure;

FIG. 27 is a flowchart illustrating a method of operating an energy storage system according to an embodiment of the present disclosure;

FIG. 28 is a flowchart illustrating a method of operating an energy storage system according to an embodiment of the present disclosure; and

FIG. 29 is a diagram for explaining a power table according to an embodiment of the present disclosure.

### DETAILED DESCRIPTION OF THE PREFERRED EMBODIMENTS

Hereinafter, embodiments of the present disclosure will be described in detail with reference to the accompanying drawings. However, it is obvious that the present disclosure is not limited to these embodiments and may be modified in various forms.

In the drawings, in order to clearly and briefly describe the present disclosure, the illustration of parts irrelevant to the description is omitted, and the same reference numerals are used for the same or extremely similar parts throughout the specification.

Hereinafter, the suffixes “module” and “unit” of elements herein are used for convenience of description and thus may be used interchangeably and do not have any distinguishable meanings or functions. Thus, the “module” and the “unit” may be interchangeably used.

It will be understood that, although the terms “first”, “second”, etc. may be used herein to describe various elements, these elements should not be limited by these terms. These terms are only used to distinguish one element from another element.

The top U, bottom D, left Le, right Ri, front F, and rear R used in drawings are used to describe a battery pack and an energy storage system including the battery pack, and may be set differently according to standard.

The height direction (h+, h−), length direction (l+, l−), and width direction (w+, w−) of the battery module used in FIGS. 10 to 13 are used to describe the battery module, and may be set differently according to standard.

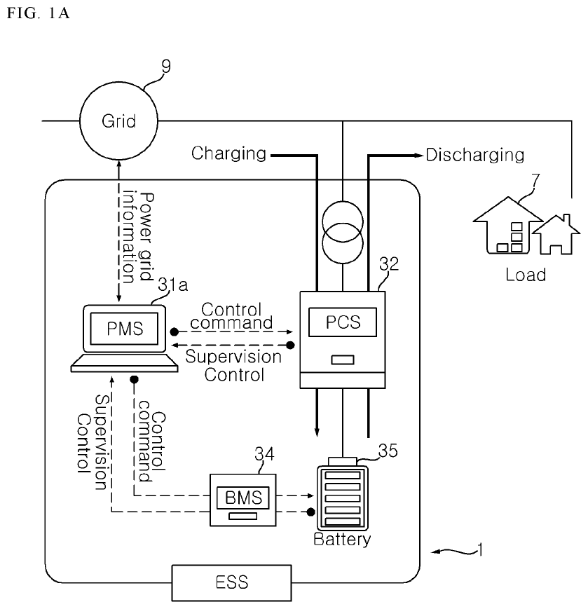

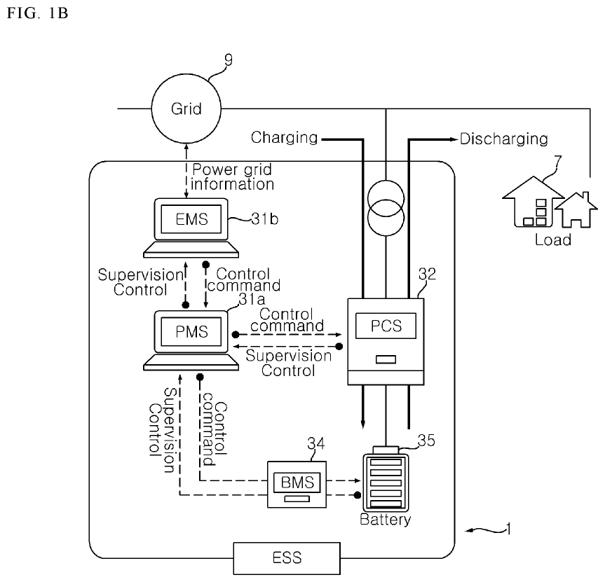

FIGS. 1A and 1B are conceptual diagrams of an energy supply system including an energy storage system according to an embodiment of the present disclosure.

Referring to FIGS. 1A and 1B, the energy supply system includes a battery 35-based energy storage system 1 in which electrical energy is stored, a load 7 that is a power demander, and a grid 9 provided as an external power supply source.

The energy storage system 1 includes a battery 35 that stores (charges) the electric energy received from the grid 9, or the like in the form of direct current (DC) or outputs (discharges) the stored electric energy to the grid 9, or the like, a power conditioning system 32 (PCS) for converting electrical characteristics (e.g. AC/DC interconversion, frequency, voltage) for charging or discharging the battery 35, and a battery management system 34 (BMS) that monitors and manages information such as current, voltage, and temperature of the battery 35.

The grid 9 may include a power generation facility for generating electric power, a transmission line, and the like. The load 7 may include a home appliance such as a refrigerator, a washing machine, an air conditioner, a TV, a robot cleaner, and a robot, a mobile electronic device such as a vehicle and a drone, and the like, as a consumer that consumes power.

The energy storage system 1 may store power from an external in the battery 35 and then output power to the external. For example, the energy storage system 1 may receive DC power or AC power from the external, store it in the battery 35, and then output the DC power or AC power to the external.

Meanwhile, since the battery 35 mainly stores DC power, the energy storage system 1 may receive DC power or convert the received AC power to DC power and store it in the battery 35, and may convert the DC power stored in the battery 35, and may supply to the grid 9 or the load 7.

At this time, the power conditioning system 32 in the energy storage system 1 may perform power conversion and voltage-charge the battery 35, or may supply the DC power stored in the battery 35 to the grid 9 or the load 7.

The energy storage system 1 may charge the battery 35 based on power supplied from the system and discharge the battery 35 when necessary. For example, the electric energy stored in the battery 35 may be supplied to the load 7 in an emergency such as a power outage, or at a time, date, or season when the electric energy supplied from the grid 9 is expensive.

The energy storage system 1 has the advantage of being able to improve the safety and convenience of new renewable energy generation by storing electric energy generated from a new renewable energy source such as sunlight, and to be used as an emergency power source. In addition, when the energy storage system 1 is used, it is possible to perform load leveling for a load having large fluctuations in time and season, and to save energy consumption and cost.

The battery management system 34 may measure the temperature, current, voltage, state of charge, and the like of the battery 35, and monitor the state of the battery 35. In addition, the battery management system 34 may control and manage the operating environment of the battery 35 to be optimized based on the state information of the battery 35.

Meanwhile, the energy storage system 1 may include a power management system 31a (PMS) that controls the power conditioning system 32.

The power management system 31a may perform a function of monitoring and controlling the states of the battery 35 and the power conditioning system 32. The power management system 31a may be a controller that controls the overall operation of the energy storage system 1.

The power conditioning system 32 may control power distribution of the battery 35 according to a control command of the power management system 31a. The power conditioning system 32 may convert power according to the grid 9, a power generation means such as photovoltaic light, and the connection state of the battery 35 and the load 7.

Meanwhile, the power management system 31a may receive state information of the battery 35 from the battery management system 34. A control command may be transmitted to the power conditioning system 32 and the battery management system 34.

The power management system 31a may include a communication means such as a Wi-Fi communication module, and a memory. Various information necessary for the operation of the energy storage system 1 may be stored in the memory. In some embodiments, the power management system 31a may include a plurality of switches and control a power supply path.

The power management system 31a and/or the battery management system 34 may calculate the SOC of the battery 35 using various well-known SOC calculation methods such as a coulomb counting method and a method of calculating a state of charge (SOC) based on an open circuit voltage (OCV). The battery 35 may overheat and irreversibly operate when the state of charge exceeds a maximum state of charge. Similarly, when the state of charge is less than or equal to the minimum state of charge, the battery may deteriorate and become unrecoverable. The power management system 31a and/or the battery management system 34 may monitor the internal temperature, the state of charge of the battery 35, and the like in real time to control an optimal usage area and maximum input/output power.

The power management system 31a may operate under the control of an energy management system (EMS) 31b, which is an upper controller. The power management system 31a may control the energy storage system 1 by receiving a command from the energy management system 31b, and may transmit the state of the energy storage system 1 to the energy management system 31b. The energy management system 31b may be provided in the energy storage system 1 or may be provided in an upper system of the energy storage system 1.

The energy management system 31b may receive information such as charge information, power usage, and environmental information, and may control the energy storage system 1 according to the energy production, storage, and consumption patterns of user. The energy management system 31b may be provided as an operating system for monitoring and controlling the power management system 31a.

The controller for controlling the overall operation of the energy storage system 1 may include the power management system 31a and/or the energy management system 31b. In some embodiments, one of the power management system 31a and the energy management system 31b may also perform the other function. In addition, the power management system 31a and the energy management system 31b may be integrated into one controller to be integrally provided.

Meanwhile, the installation capacity of the energy storage system 1 varies according to the customer's installation condition, and a plurality of the power conditioning systems 32 and the batteries 35 may be connected to expand to a required capacity.

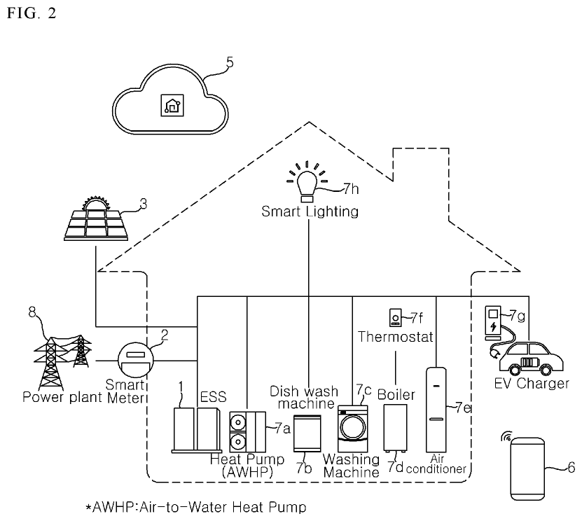

The energy storage system 1 may be connected to at least one generating plant (refer to 3 of FIG. 2) separately from the grid 9. A generating plant 3 may include a wind generating plant that outputs DC power, a hydroelectric generating plant that outputs DC power using hydroelectric power, a tidal generating plant that outputs DC power using tidal power, thermal generating plant that outputs DC power using heat such as geothermal heat, or the like. Hereinafter, for convenience of description, the photovoltaic plant will be mainly described as the generating plant 3.

FIG. 2 is a conceptual diagram of a home energy service system including an energy storage system according to an embodiment of the present disclosure.

The home energy service system according to an embodiment of the present disclosure may include the energy storage system 1, and may be configured as a cloud 5-based intelligent energy service platform for integrated energy service management.

Referring to FIG. 2, the home energy service system may be implemented in a home, and may manage the supply, consumption, and storage of energy (power) in the home.

The energy storage system 1 may be connected to a grid 9 such as a power plant 8, a generating plant such as a photovoltaic generator 3, a plurality of loads 7a to 7g, and sensors (not shown) to configure a home energy service system.

The loads 7a to 7g may be a heat pump 7a, a dishwasher 7b, a washing machine 7c, a boiler 7d, an air conditioner 7e, a thermostat 7f, an electric vehicle (EV) charger 7g, a smart lighting 7h, and the like.

The home energy service system may include other loads in addition to the smart devices illustrated in FIG. 2. For example, the home energy service system may include several lights in addition to the smart lighting 7h having one or more communication modules. In addition, the home energy service system may include a home appliance that does not include a communication module.

Some of the loads 7a to 7g are set as essential loads, so that power may be supplied from the energy storage system 1 when a power outage occurs. For example, a refrigerator and at least some lighting devices may be set as essential loads that require backup in case of power failure.

Meanwhile, the energy storage system 1 can communicate with the devices 7a to 7g, and the sensors through a short-range wireless communication module. For example, the short-range wireless communication module may be at least one of Bluetooth, Wi-Fi, and Zigbee. In addition, the energy storage system 1, the devices 7a to 7g, and the sensors may be connected to an Internet network.

The energy management system 31b may communicate with the energy storage system 1, the devices 7a to 7g, the sensors, and the cloud 5 through an Internet network, and a short-range wireless communication.

The energy management system 31b and/or the cloud 5 may transmit information received from the energy storage device 1, the devices 7a to 7g, and sensors and information determined using the received information to the terminal 6. The terminal 6 may be implemented as a smart phone, a PC, a notebook computer, a tablet PC, or the like. In some embodiments, an application for controlling the operation of the home energy service system may be installed and executed in the terminal 6.

The home energy service system may include a meter 2. The meter 2 may be provided between the power grid 9 such as the power plant 8 and the energy storage system 1. The meter 2 may measure the amount of power supplied to the home from the power plant 8 and consumed. In addition, the meter 2 may be provided inside the energy storage system 1. The meter 2 may measure the amount of power discharged from the energy storage system 1. The amount of power discharged from the energy storage system 1 may include the amount of power supplied (sold) from the energy storage system 1 to the power grid 9, and the amount of power supplied from the energy storage system 1 to the devices 7a to 7g.

The energy storage system 1 may store the power supplied from the photovoltaic generator 2 and/or the power plant 8, or the residual power remaining after the supplied power is consumed.

Meanwhile, the meter 2 may be implemented of a smart meter. The smart meter may include a communication module for transmitting information related to power usage to the cloud 5 and/or the energy management system 31b.

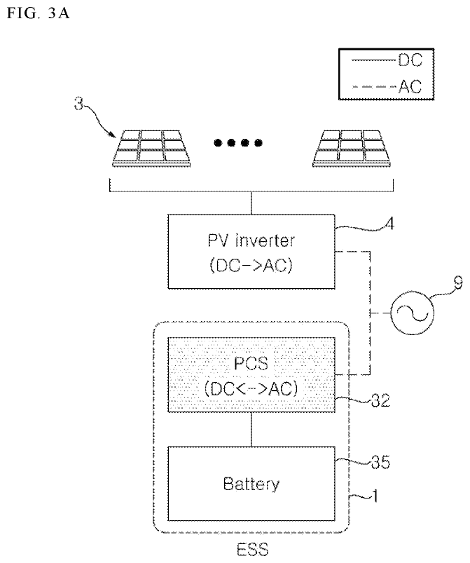

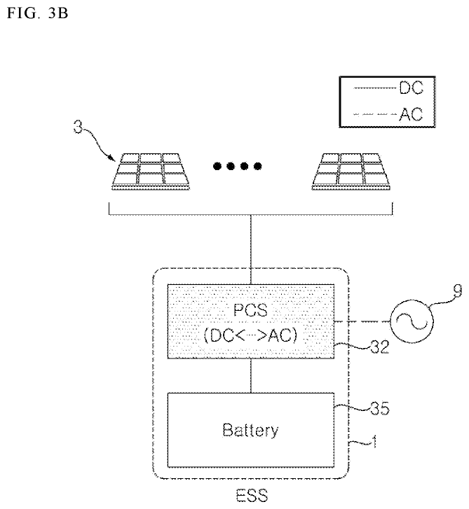

FIGS. 3A and 3B are diagrams illustrating an energy storage system installation type according to an embodiment of the present disclosure.

The home energy storage system 1 may be divided into an AC-coupled ESS (see FIG. 3A) and a DC-coupled ESS (see FIG. 3B) according to an installation type.

The photovoltaic plant includes a photovoltaic panel 3. Depending on the type of photovoltaic installation, the photovoltaic plant may include a photovoltaic panel 3 and a photovoltaic (PV) inverter 4 that converts DC power supplied from the photovoltaic panel 3 into AC power (see FIG. 3A). Thus, it is possible to implement the system more economically, as the energy storage system 1 independent of the existing grid 9 can be used.

In addition, according to an embodiment, the power conditioning system 32 of the energy storage system 1 and the PV inverter 4 may be implemented as an integrated power conversion device (see FIG. 3B). In this case, the DC power output from the photovoltaic panel 3 is input to the power conditioning system 32. The DC power may be transmitted to and stored in the battery 35. In addition, the power conditioning system 32 may convert DC power into AC power and supply to the grid 9. Accordingly, a more efficient system implementation can be achieved.

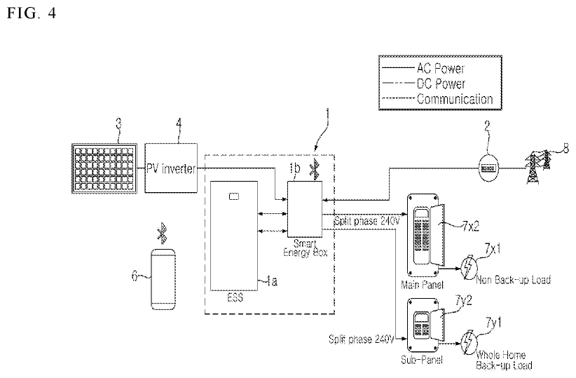

FIG. 4 is a conceptual diagram of a home energy service system including an energy storage system according to an embodiment of the present disclosure.

Referring to FIG. 4, the energy storage system 1 may be connected to the grid 9 such as the power plant 8, the power plant such as the photovoltaic generator 3, and a plurality of loads 7x1 and 7y1.

Electrical energy generated by the photovoltaic generator 3 may be converted in the PV inverter 4 and supplied to the grid 9, the energy storage system 1, and the loads 7x1 and 7y1. As described with reference to FIG. 3, according to the type of installation, the electrical energy generated by the photovoltaic generator 3 may be converted in the energy storage system 1, and supplied to the grid 9, the energy storage system 1, and the loads 7x1, 7y1.

Meanwhile, the energy storage system 1 is provided with one or more wireless communication modules, and may communicate with the terminal 6. The user may monitor and control the state of the energy storage system 1 and the home energy service system through the terminal 6. In addition, the home energy service system may provide a cloud 5 based service. The user may communicate with the cloud 5 through the terminal 6 regardless of location and monitor and control the state of the home energy service system.

According to an embodiment of the present disclosure, the above-described battery 35, the battery management system 34, and the power conditioning system 32 may be disposed inside one casing 12. Since the battery 35, the battery management system 34, and the power conditioning system 32 integrated in one casing 12 can store and convert power, they may be referred to as an all-in-one energy storage system 1a.

In addition, in separate enclosures 1b outside the casing 12, a configuration for power distribution such as a power management system 31a, an auto transfer switch ATS, a smart meter, and a switch, and a communication module for communication with the terminal 6, the cloud 5, and the like may be disposed. A configuration in which configurations related to power distribution and management are integrated in one enclosure 1 may be referred to as a smart energy box 1b.

The above-described power management system 31a may be received in the smart energy box 1b. A controller for controlling the overall power supply connection of the energy storage system 1 may be disposed in the smart energy box 1b. The controller may be the above mentioned power management system 31a.

In addition, switches are received in the smart energy box 1b to control the connection state of the connected grid power source 8, 9, the photovoltaic generator 3, the battery 35 of all-in-one energy storage system 1a, and loads 7x1, 7y1. The loads 7x1, 7y1 may be connected to the smart energy box 1b through the load panel 7x2, 7y2.

Meanwhile, the smart energy box 1b is connected to the grid power source 8, 9 and the photovoltaic generator 3. In addition, when a power failure occurs in the system 8, 9, the auto transfer switch ATS that is switched so that the electric energy which is produced by the photovoltaic generator 3 or stored in the battery 35 is supplied to a certain load 7y1 may be disposed in the smart energy box 1b.

Alternatively, the power management system 31a may perform an auto transfer switch ATS function. For example, when a power failure occurs in the system 8, 9, the power management system 31a may control a switch such as a relay so that the electrical energy that is produced by the photovoltaic generator 3 or stored in the battery 35 is transmitted to a certain load 7y1.

Meanwhile, a current sensor, a smart meter, or the like may be disposed in each current supply path. Electric energy of the electricity produced through the energy storage system 1 and the photovoltaic generator 3 may be measured and managed by a smart meter (at least a current sensor).

The energy storage system 1 according to an embodiment of the present disclosure includes at least an all-in-one energy storage system 1a. In addition, the energy storage system 1 according to an embodiment of the present disclosure includes the all-in-one energy storage system 1a and the smart energy box 1b, thereby providing an integrated service that can simply and efficiently perform storage, supply, distribution, communication, and control of power.

Meanwhile, the energy storage system 1 according to an embodiment of the present disclosure may operate in a plurality of operation modes. In a PV self consumption mode, photovoltaic generation power is first used in the load, and the remaining power is stored in the energy storage system 1. For example, when more power is generated than the amount of power used by the loads 7x1 and 7y1 in the photovoltaic generator 3 during the day, the battery 35 is charged.

In a charge/discharge mode based on a rate system, four time zones may be set and input, the battery 35 may be discharged during a time period when the electric rate is expensive, and the battery 35 may be charged during a time period when the electric rate is cheap. The energy storage system 1 may help a user to save electric rate in the charge/discharge mode based on a rate system.

A backup-only mode is a mode for emergency situations such as power outages, and can operate, with the highest priority, such that when a typhoon is expected by a weather forecast or there is a possibility of other power outages, the battery 35 may be charged up to a maximum and supplied to an essential load 7y1 in an emergency.

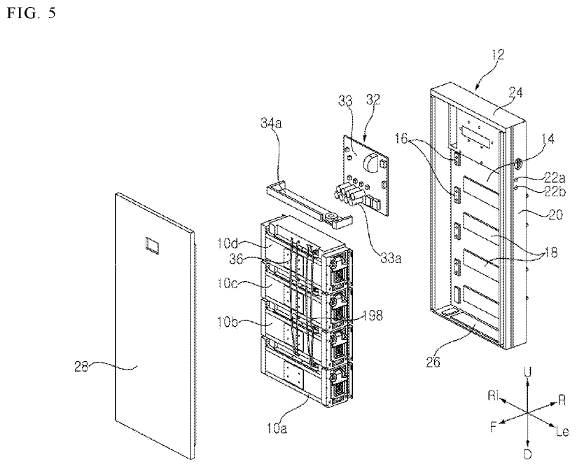

The energy storage system 1 of the present disclosure will be described with reference to FIGS. 5 to 7. More particularly, detailed structures of the all-in-one energy storage system 1a are disclosed.

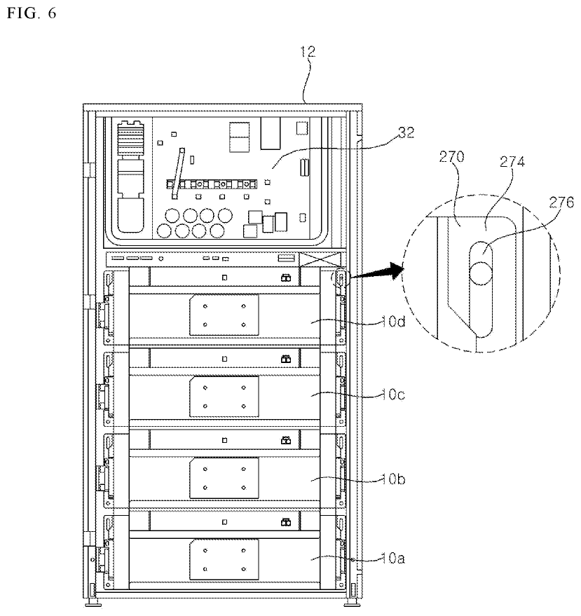

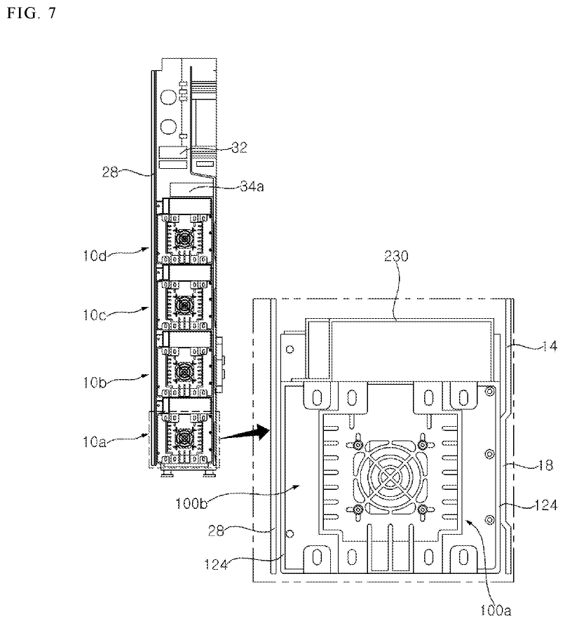

FIG. 5 is an exploded perspective view of an energy storage system including a plurality of battery packs according to an embodiment of the present disclosure, FIG. 6 is a front view of an energy storage system in a state in which a door is removed, FIG. 7 is a cross-sectional view of one side of FIG. 6.

Referring to FIG. 5, the energy storage system 1 includes at least one battery pack 10, a casing 12 forming a space in which at least one battery pack 10 is disposed, a door 28 for opening and closing the front surface of the casing 12, a power conditioning system 32 (PCS) which is disposed inside the casing 12 and converts the characteristics of electricity so as to charge or discharge a battery, and a battery management system (BMS) that monitors information such as current, voltage, and temperature of the battery cell 101.

The casing 12 may have an open front shape. The casing 12 may include a casing rear wall 14 covering the rear, a pair of casing side walls 20 extending to the front from both side ends of the casing rear wall 14, a casing top wall 24 extending to the front from the upper end of the casing rear wall 14, and a casing base 26 extending to the front from the lower end of the casing rear wall 14. The casing rear wall 14 includes a pack fastening portion 16 formed to be fastened with the battery pack 10 and a contact plate 18 protruding to the front to contact the heat dissipation plate 124 of the battery pack 10.

Referring to FIG. 5, the contact plate 18 may be disposed to protrude to the front from the casing rear wall 14. The contact plate 18 may be disposed to contact one side of the heat dissipation plate 124. Accordingly, heat emitted from the plurality of battery cells 101 disposed inside the battery pack 10 may be radiated to the outside through the heat dissipation plate 124 and the contact plate 18.

A switch 22a, 22b for turning on/off the power of the energy storage system 1 may be disposed in one of the pair of casing sidewalls 20. In the present disclosure, a first switch 22a and a second switch 22b are disposed to enhance the safety of the power supply or the safety of the operation of the energy storage system 1.

The power conditioning system 32 may include a circuit substrate 33 and an insulated gate bipolar transistor (IGBT) that is disposed in one side of the circuit substrate 33 and performs power conversion.

The battery monitoring system may include a battery pack circuit substrate 220 disposed in each of the plurality of battery packs 10a, 10b, 10c, 10d, and a main circuit substrate 34a which is disposed inside the casing 12 and connected to a plurality of battery pack circuit substrates 220 through a communication line 36.

The main circuit substrate 34a may be connected to the battery pack circuit substrate 220 disposed in each of the plurality of battery packs 10a, 10b, 10c, and 10d by the communication line 36. The main circuit substrate 34a may be connected to a power line 198 extending from the battery pack 10.

At least one battery pack 10a, 10b, 10c, and 10d may be disposed inside the casing 12. A plurality of battery packs 10a, 10b, 10c, and 10d are disposed inside the casing 12. The plurality of battery packs 10a, 10b, 10c, and 10d may be disposed in the vertical direction.

The plurality of battery packs 10a, 10b, 10c, and 10d may be disposed such that the upper end and lower end of each side bracket 250 contact each other. At this time, each of the battery packs 10a, 10b, 10c, and 10d disposed vertically is disposed such that the battery module 100a, 100b and the top cover 230 do not contact each other.

Each of the plurality of battery packs 10 is fixedly disposed in the casing 12. Each of the plurality of battery packs 10a, 10b, 10c, and 10d is fastened to the pack fastening portion 16 disposed in the casing rear wall 14. That is, the fixing bracket 270 of each of the plurality of battery packs 10a, 10b, 10c, and 10d is fastened to the pack fastening portion 16. The pack fastening portion 16 may be disposed to protrude to the front from the casing rear wall 14 like the contact plate 18.

The contact plate 18 may be disposed to protrude to the front from the casing rear wall 14. Accordingly, the contact plate 18 may be disposed to be in contact with one heat dissipation plate 124 included in the battery pack 10.

One battery pack 10 includes two battery modules 100a and 100b. Accordingly, two heat dissipation plates 124 are disposed in one battery pack 10. One heat dissipation plate 124 included in the battery pack 10 is disposed to face the casing rear wall 14, and the other heat dissipation plate 124 is disposed to face the door 28.

One heat dissipation plate 124 is disposed to contact the contact plate 18 disposed in the casing rear wall 14, and the other heat dissipation plate 124 is disposed to be spaced apart from the door 28. The other heat dissipation plate 124 may be cooled by air flowing inside the casing 12.

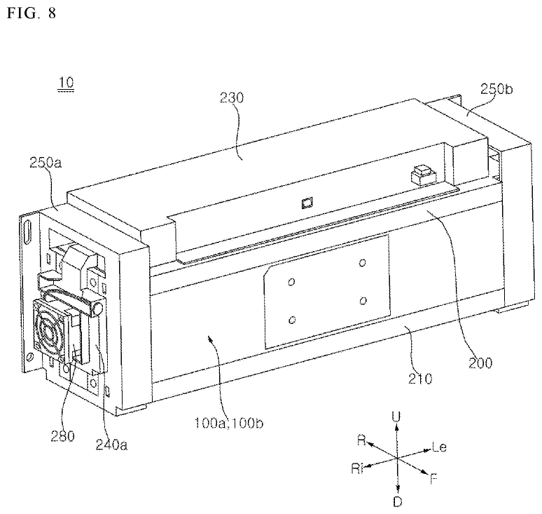

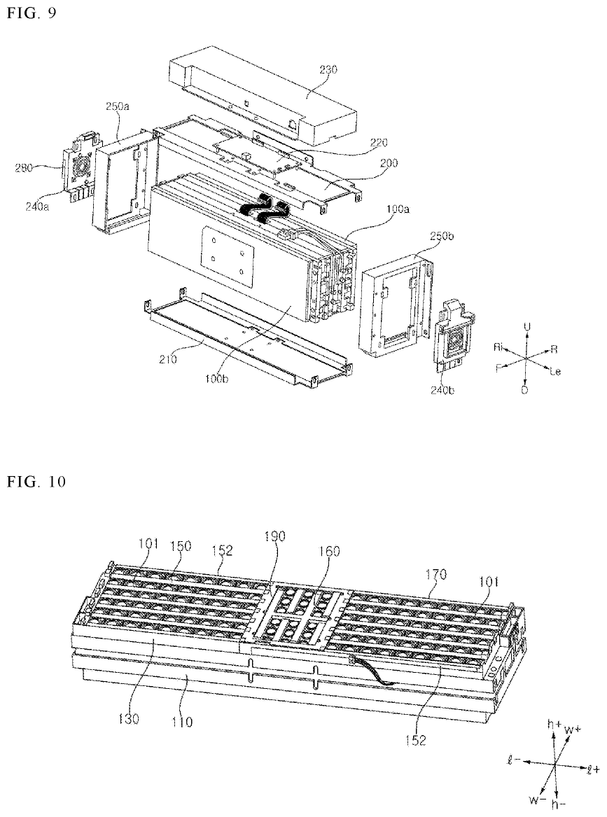

FIG. 8 is a perspective view of a battery pack according to an embodiment of the present disclosure, and FIG. 9 is an exploded view of a battery pack according to an embodiment of the present disclosure.

The energy storage system of the present disclosure may include a battery pack 10 in which a plurality of battery cells 101 are connected in series and in parallel. The energy storage system may include a plurality of battery packs 10a, 10b, 10c, and 10d (refer to FIG. 5).

First, a configuration of one battery pack 10 will be described with reference to FIGS. 8 to 9. The battery pack 10 includes at least one battery module 100a, 100b to which a plurality of battery cells 101 are connected in series and parallel, an upper fixing bracket 200 which is disposed in an upper portion of the battery module 100a, 100b and fixes the disposition of the battery module 100a, 100b, a lower fixing bracket 210 which is disposed in a lower portion of the battery module 100 and fixes the disposition of the battery modules 100a and 100b, a pair of side brackets 250a, 250b which are disposed in both side surfaces of the battery module 100a, 100b and fixes the disposition of the battery module 100a, 100b, a pair of side covers 240a, 240b which are disposed in both side surfaces of the battery module 100a, 100b, and in which a cooling hole 242a is formed, a cooling fan 280 which is disposed in one side surface of the battery module 100a, 100b and forms an air flow inside the battery module 100a, 100b, a battery pack circuit substrate 220 which is disposed in the upper side of the upper fixing bracket 200 and collects sensing information of the battery module 100a, 100b, and a top cover 230 which is disposed in the upper side of the upper fixing bracket 200 and covers the upper side of the battery pack circuit substrate 220.

The battery pack 10 includes at least one battery module 100a, 100b. Referring to FIG. 2, the battery pack 10 of the present disclosure includes a battery module assembly 100 configured of two battery modules 100a, 100b which are electrically connected to each other and physically fixed. The battery module assembly 100 includes a first battery module 100a and a second battery module 100b disposed to face each other.

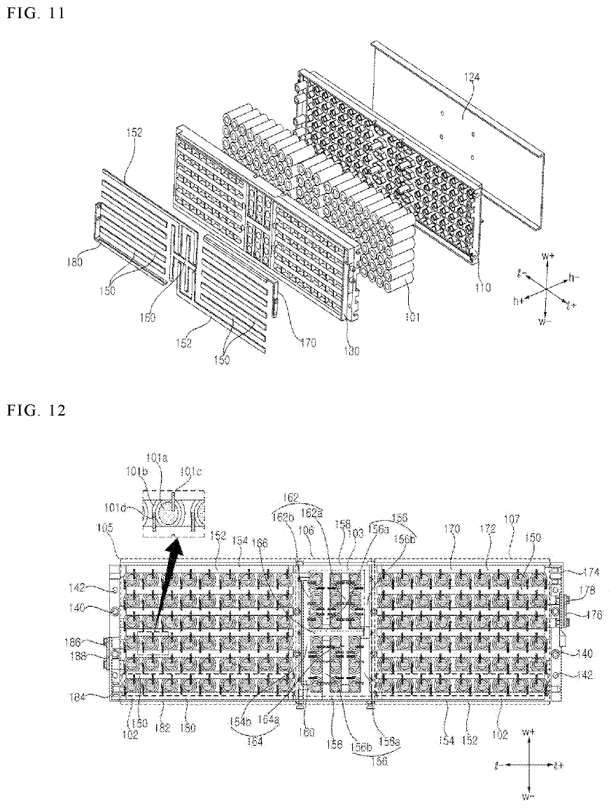

FIG. 10 is a perspective view of a battery module according to an embodiment of the present disclosure and FIG. 11 is an exploded view of a battery module according to an embodiment of the present disclosure.

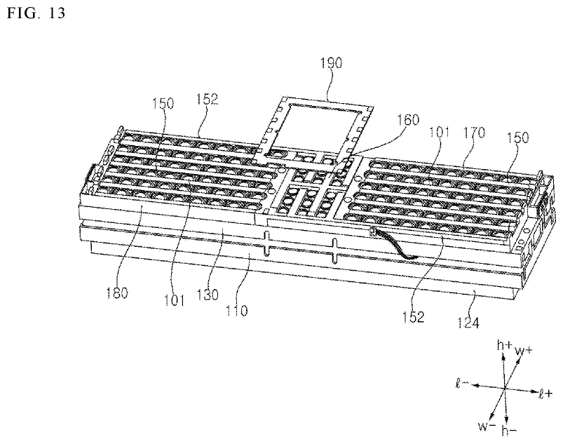

FIG. 12 is a front view of a battery module according to an embodiment of the present disclosure and FIG. 13 is an exploded perspective view of a battery module and a sensing substrate according to an embodiment of the present disclosure.

Hereinafter, the first battery module 100a of the present disclosure will be described with reference to FIGS. 10 to 13. The configuration and shape of the first battery module 100a described below may also be applied to the second battery module 100b.

The battery module described in FIGS. 10 to 13 may be described in a vertical direction based on the height direction (h+, h−) of the battery module. The battery module described in FIGS. 10 to 13 may be described in the left-right direction based on the length direction (l+, l−) of the battery module. The battery module described in FIGS. 10 to 13 may be described in the front-rear direction based on the width direction (w+, w−) of the battery module. The direction setting of the battery module used in FIGS. 10 to 13 may be different from the direction setting in a structure of the battery pack 10 described in other drawings. In the battery module described in FIGS. 10 to 13, the width direction (w+, w−) of the battery module may be described as a first direction, and the length direction (l+, l−) of the battery module may be described as a second direction.

The first battery module 100a includes a plurality of battery cells 101, a first frame 110 for fixing the lower portion of the plurality of battery cells 101, a second frame 130 for fixing the upper portion of the plurality of battery cells 101, a heat dissipation plate 124 which is disposed in the lower side of the first frame 110 and dissipates heat generated from the battery cell 101, a plurality of bus bars which are disposed in the upper side of the second frame 130 and electrically connect the plurality of battery cells 101, and a sensing substrate 190 which is disposed in the upper side of the second frame 130 and detects information of the plurality of battery cells 101.

The first frame 110 and the second frame 130 may fix the disposition of the plurality of battery cells 101. In the first frame 110 and the second frame 130, the plurality of battery cells 101 are disposed to be spaced apart from each other. Since the plurality of battery cells 101 are spaced apart from each other, air may flow into a space between the plurality of battery cells 101 by the operation of the cooling fan 280 described below.

The first frame 110 fixes the lower end of the battery cell 101. The first frame 110 includes a lower plate 112 having a plurality of battery cell holes 112a formed therein, a first fixing protrusion 114 which protrudes upward from the upper surface of the lower plate 112 and fixes the disposition of the battery cell 101, a pair of first sidewalls 116 which protrudes upward from both ends of the lower plate 112, and a pair of first end walls 118 which protrudes upward from both ends of the lower plate 112 and connects both ends of the pair of first side walls 116.

The pair of first sidewalls 116 may be disposed parallel to a first cell array 102 described below. The pair of first end walls 118 may be disposed perpendicular to the pair of first side walls 116.

Referring to FIG. 13, the first frame 110 includes a first fastening protrusion 120 protruding to be fastened to the second frame 130, and a module fastening protrusion 122 protruding to be fastened with the first frame 110 included in the second battery module 100b disposed adjacently. A frame screw 125 for fastening the second frame 130 and the first frame 110 is disposed in the first fastening protrusion 120. A module screw 194 for fastening the first battery module 100a and the second battery module 100b is disposed in the module fastening protrusion 122. The frame screw 125 fastens the second frame 130 and the first frame 110. The frame screw 125 may fix the disposition of the plurality of battery cells 101 by fastening the second frame 130 and the first frame 110.

The plurality of battery cells 101 are fixedly disposed in the second frame 130 and the first frame 110. A plurality of battery cells 101 are disposed in series and parallel. The plurality of battery cells 101 are fixedly disposed by a first fixing protrusion 114 of the first frame 110 and a second fixing protrusion 134 of the second frame 130.

Referring to FIG. 12, the plurality of battery cells 101 are spaced apart from each other in the length direction (l+, l−) and the width direction (w+, w−) of the battery module.

The plurality of battery cells 101 includes a cell array connected in parallel to one bus bar. The cell array may refer to a set electrically connected in parallel to one bus bar.

The first battery module 100a may include a plurality of cell arrays 102 and 103 electrically connected in series. The plurality of cell arrays 102 and 103 are electrically connected to each other in series. The first battery module 100a has a plurality of cell arrays 102 and 103 connected in series.

The plurality of cell arrays 102 and 103 may include a first cell array 102 in which a plurality of battery cells 101 are disposed in a straight line, and a second cell array 103 in which a plurality of cell array rows and columns are disposed.

The first battery module 100a may include a first cell array 102 in which a plurality of battery cells 101 are disposed in a straight line, and a second cell array 103 in which a plurality of rows and columns are disposed.

Referring to FIG. 12, in the first cell array 102, a plurality of battery cells 101 are disposed in the left and right side in the length direction (l+, l−) of the first battery module 100a. The plurality of first cell arrays 102 are disposed in the front and rear side in the width direction (w+, w−) of the first battery module 100a.

Referring to FIG. 12, the second cell array 103 includes a plurality of battery cells 101 spaced apart from each other in the width direction (w+, w−) and the length direction (l+, l−) of the first battery module 100a.

The first battery module 100a includes a first cell group 105 in which a plurality of first cell arrays 102 are disposed in parallel, and a second cell group 106 that includes at least one second cell array 103 and is disposed in one side of the first cell group 105.

The first battery module 100a includes a first cell group 105 in which a plurality of first cell arrays 102 are connected in series, and a third cell group 107 in which a plurality of first cell arrays 102 are connected in series, and which are spaced apart from the first cell group 105. The second cell group is disposed between the first cell group 105 and the third cell group 107.

In the first cell group 105, a plurality of first cell arrays 102 are connected in series. In the first cell group 105, a plurality of first cell arrays 102 are spaced apart from each other in the width direction of the battery module. The plurality of first cell arrays 102 included in the first cell group 105 are spaced apart in a direction perpendicular to the direction in which the plurality of battery cells 101 included in each of the first cell arrays 102 are disposed.

Referring to FIG. 12, nine battery cells 101 connected in parallel are disposed in each of the first cell array 102 and the second cell array 103. Referring to FIG. 12, in the first cell array 102, nine battery cells 101 are spaced apart from each other in the length direction of the battery module. In the second cell array 103, nine battery cells are spaced apart from each other in a plurality of rows and a plurality of columns. Referring to FIG. 12, in the second cell array 103, three battery cells 101 that are spaced apart from each other in the width direction of the battery module are spaced apart from each other in the length direction of the battery module. Here, the length direction (l+, l−) of the battery module may be set as a column direction, and the width direction (w+, w−) of the battery module may be set as a row direction.

Referring to FIG. 12, each of the first cell group 105 and the third cell group 107 is disposed such that six first cell arrays 102 are connected in series. In each of the first cell group 105 and the third cell group 107, six first cell arrays 102 are spaced apart from each other in the width direction of the battery module.

Referring to FIG. 12, the second cell group 106 includes two second cell arrays 103. The two second cell arrays 103 are spaced apart from each other in the width direction of the battery module. The two second cell arrays 103 are connected in parallel to each other. Each of the two second cell arrays 103 is disposed symmetrically with respect to the horizontal bar 166 of a third bus bar 160 described below.

The first battery module 100a includes a plurality of bus bars which are disposed between the plurality of battery cells 101, and electrically connect the plurality of battery cells 101. Each of the plurality of bus bars connects in parallel the plurality of battery cells included in a cell array disposed adjacent to each other. Each of the plurality of bus bars may connect in series two cell arrays disposed adjacent to each other.

The plurality of bus bars includes a first bus bar 150 connecting the two first cell arrays 102 in series, a second bus bar 152 connecting the first cell array 102 and the second cell array 103 in series, and a third bus bar 160 connecting the two second cell arrays 103 in series.

The plurality of bus bars include a fourth bus bar 170 connected to one first cell array 102 in series. The plurality of bus bars include a fourth bus bar 170 which is connected to one first cell array 102 in series and connected to other battery module 100b included in the same battery pack 10, and a fifth bus bar 180 which is connected to one first cell array 102 in series and connected to one battery module included in other battery pack 10. The fourth bus bar 170 and the fifth bus bar 180 may have the same shape.

The first bus bar 150 is disposed between two first cell arrays 102 spaced apart from each other in the length direction of the battery module. The first bus bar 150 connects in parallel a plurality of battery cells 101 included in one first cell array 102. The first bus bar 150 connects in series the two first cell arrays 102 disposed in the length direction (l+, l−) of the battery module.

Referring to FIG. 12, it is electrically connected to a positive terminal 101a of each of the battery cells 101 of the first cell array 102 which is disposed in the front in the width direction (w+, w−) of the battery module with respect to the first bus bar 150, and is electrically connected to a negative terminal 101b of each of the battery cells 101 of the first cell array 102 which is disposed in the rear in the width direction (w+, w−) of the battery module with respect to the first bus bar 150.

Referring to FIG. 12, in the battery cell 101, the positive terminal 101a and the negative terminal 101b are partitioned in the upper end thereof. In the battery cell 101, the positive terminal 101a is disposed in the center of a top surface formed in a circle, and the negative terminal 101b is disposed in the circumference portion of the positive terminal 101a. Each of the plurality of battery cells 101 may be connected to each of the plurality of bus bars through a cell connector 101c, 101d.

The first bus bar 150 has a straight bar shape. The first bus bar 150 is disposed between the two first cell arrays 102. The first bus bar 150 is connected to the positive terminal of the plurality of battery cells 101 included in the first cell array 102 disposed in one side, and is connected to the negative terminal of the plurality of battery cells 101 included in the first cell array 102 disposed in the other side.

The first bus bar 150 is disposed between the plurality of first cell arrays 102 disposed in the first cell group 105 and the third cell group 107.

The second bus bar 152 connects the first cell array 102 and the second cell array 103 in series. The second bus bar 152 includes a first connecting bar 154 connected to the first cell array 102 and a second connecting bar 156 connected to the second cell array 103. The second bus bar 152 is disposed perpendicular to the first connecting bar 154. The second bus bar 152 includes an extension portion 158 that extends from the first connecting bar 154 and is connected to the second connecting bar 156.

The first connecting bar 154 may be connected to different electrode terminals of the second connecting bar 156 and the battery cell. Referring to FIG. 12, the first connecting bar 154 is connected to the positive terminal 101a of the battery cell 101 included in the first cell array 102, and the second connecting bar 156 is connected to the negative terminal 101b of the battery cell 101 included in the second cell array 103. However, this is just an embodiment and it is possible to be connected to opposite electrode terminal.

The first connecting bar 154 is disposed in one side of the first cell array 102. The first connecting bar 154 has a straight bar shape extending in the length direction of the battery module. The extension portion 158 has a straight bar shape extending in the direction in which the first connecting bar 154 extends.

The second connecting bar 156 is disposed perpendicular to the first connecting bar 154. The second connecting bar 156 has a straight bar shape extending in the width direction (w+, w−) of the battery module. The second connecting bar 156 may be disposed in one side of the plurality of battery cells 101 included in the second cell array 103. The second connecting bar 156 may be disposed between the plurality of battery cells 101 included in the second cell array 103. The second connecting bar 156 extends in the width direction (w+, w−) of the battery module, and is connected to the battery cell 101 disposed in one side or both sides.

The second connecting bar 156 includes a second-first connecting bar 156a and a second-second connecting bar 156b spaced apart from the second-first connecting bar 156a. The second-first connecting bar 156a is disposed between the plurality of battery cells 101, and the second-second connecting bar 156b is disposed in one side of the plurality of battery cells 101.

The third bus bar 160 connects in series the two second cell arrays 103 spaced apart from each other. The third bus bar 160 includes a first vertical bar 162 connected to one cell array among the plurality of second cell arrays 103, a second vertical bar 164 connected to the other cell array among the plurality of second cell arrays 103, and a horizontal bar 166 which is disposed between the plurality of second cell arrays 103 and connected to the first vertical bar 162 and the second vertical bar 164. The first vertical bar 162 and the second vertical bar 164 may be symmetrically disposed with respect to the horizontal bar 166.

A plurality of second vertical bars 164 may be disposed to be spaced apart from each other in the length direction (l+, l−) of the battery module. Referring to FIG. 12, a second-first vertical bar 164a, and a second-second vertical bar 164b which is spaced apart from the second-first vertical bar 164a in the length direction of the battery module may be included.

The first vertical bar 162 or the second vertical bar 164 may be disposed parallel to the second connecting bar 156 of the second bus bar 152. The battery cell 101 included in the second cell array 103 may be disposed between the first vertical bar 162 and the second connecting bar 156. Similarly, the battery cell 101 included in the second cell array 103 may be disposed between the second vertical bar 164 and the second connecting bar 156.

The first battery module 100a includes a fourth bus bar 170 connected to the second battery module 100b included in the same battery pack 10, and a fifth bus bar 180 connected to one battery module included in other battery pack 10.

The fourth bus bar 170 is connected to the second battery module 100b which is another battery module included in the same battery pack 10. That is, the fourth bus bar 170 is connected to the second battery module 100b included in the same battery pack 10 through a high current bus bar 196 described below.

The fifth bus bar 180 is connected to other battery pack 10. That is, the fifth bus bar 180 may be connected to a battery module included in other battery pack 10 through a power line 198 described below.

The fourth bus bar 170 includes a cell connecting bar 172 which is disposed in one side of the first cell array 102, and connects in parallel the plurality of battery cells 101 included in the first cell array 102, and an additional connecting bar 174 which is vertically bent from the cell connecting bar 172 and extends along the end wall of the second frame 130.

The cell connecting bar 172 is disposed in the second sidewall 136 of the second frame 130. The cell connecting bar 172 may be disposed to surround a portion of the outer circumference of the second sidewall 136. The additional connecting bar 174 is disposed outside the second end wall 138 of the second frame 130.

The additional connecting bar 174 includes a connecting hanger 176 to which the high current bus bar 196 is connected. The connecting hanger 176 is provided with a groove 178 opened upward. The high current bus bar 196 may be seated on the connecting hanger 176 through the groove 178. The high current bus bar 196 may be fixedly disposed in the connecting hanger 176 through a separate fastening screw while seated on the connecting hanger 176.

The fifth bus bar 180 may have the same configuration and shape as the fourth bus bar. That is, the fifth bus bar 180 includes a cell connecting bar 182 and an additional connecting bar 184. The additional connecting bar 184 of the fifth bus bar 180 includes a connecting hanger 186 to which a terminal 198a of the power line 198 is connected. The connecting hanger 186 is provided with a groove 188 into which the terminal 198a of the power line 198 is inserted.

The sensing substrate 190 is electrically connected to a plurality of bus bars disposed inside the first battery module 100a. The sensing substrate 190 may be electrically connected to each of the plurality of first bus bars 150, the plurality of second bus bars 152, the third bus bar 160, and the plurality of fourth bus bars 170, respectively. The sensing substrate 190 is connected to each of the plurality of bus bars, so that information such as voltage and current values of the plurality of battery cells 101 included in the plurality of cell arrays can be obtained.

The sensing substrate 190 may have a rectangular ring shape. The sensing substrate 190 may be disposed between the first cell group 105 and the third cell group 107. The sensing substrate 190 may be disposed to surround the second cell group 106. The sensing substrate 190 may be disposed to partially overlap the second bus bar 152.

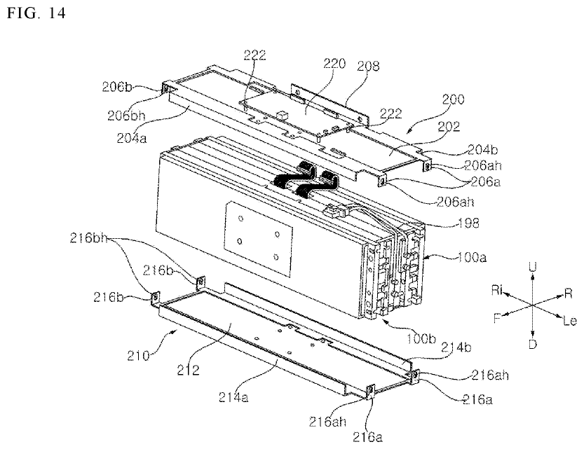

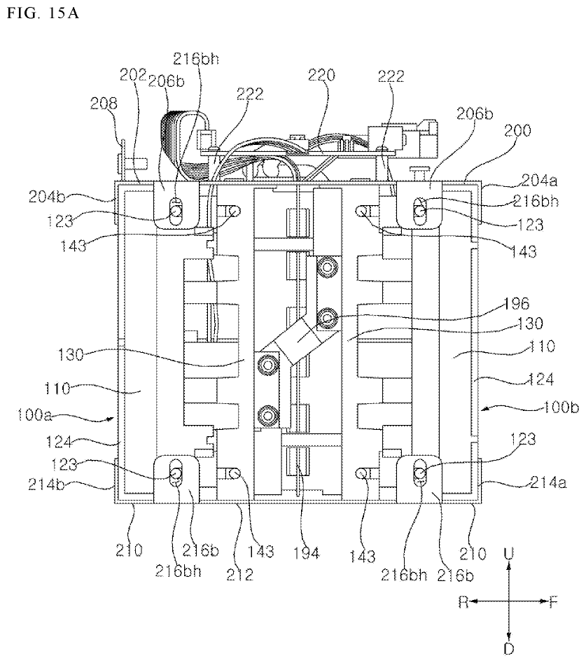

FIG. 14 is a perspective of a battery module and a battery pack circuit substrate according to an embodiment of the present disclosure, FIG. 15A is one side view in a coupled state of FIG. 14, and FIG. 15B is the other side view in a coupled state of FIG. 14.

Referring to FIGS. 14 to 15B, the battery pack 10 includes an upper fixing bracket 200 which is disposed in an upper portion of the battery module 100a, 100b and fixes the battery module 100a, 100b, a lower fixing bracket 210 which is disposed in a lower portion of the battery module 100 and fixes the battery modules 100a and 100b, a battery pack circuit substrate 220 which is disposed in an upper side of the upper fixing bracket 200 and collects sensing information of the battery module 100a, 100b, and a spacer 222 which separates the battery pack circuit substrate 220 from the upper fixing bracket 200.

The upper fixing bracket 200 is disposed in an upper side of the battery module 100a, 100b. The upper fixing bracket 200 includes an upper board 202 that covers at least a portion of the upper side of the battery module 100a, 100b, a first upper holder 204a which is bent downward from the front end of the upper board 202 and disposed in contact with the front portion of the battery module 100a, 100b, a second upper holder 204b which is bent downward from the rear end of the upper board 202 and disposed in contact with the rear portion of the battery module 100a, 100b, a first upper mounter 206a which is bent downward from one side end of the upper board 202 and coupled to one side of the battery module 100a, 100b, a second upper mounter 206b which is bent downward from the other side end of the upper board 202 and coupled to the other side of the battery module 100a, 100b, and a rear bender 208 which is bent upward from the rear end of the upper board 202.

The upper board 202 is disposed in the upper side of the battery module 100a, 100b. Each of the first upper mounter 206a and the second upper mounter 206b is disposed to surround the front and rear of the battery module 100a, 100b. Accordingly, the first upper mounter 206a and the second upper mounter 206b may maintain a state in which the first battery module 100a and the second battery module 100b are coupled.

A pair of first upper mounters 206a spaced apart in the front-rear direction are disposed in one side end of the upper board 202. A pair of second upper mounters 206b spaced apart in the front-rear direction are disposed in the other side end of the upper board 202.

The pair of first upper mounters 206a are coupled to the first fastening hole 123 formed in the first battery module 100a and the second battery module 100b. In each of the pair of first upper mounters 206a, a first upper mounter hole 206ah is formed in a position corresponding to the first fastening hole 123. Similarly, the pair of second upper mounters 206b are coupled to the first fastening hole 123 formed in the first battery module 100a and the second battery module 100b, and a second upper mounter hole 206bh is formed in a position corresponding to the first fastening hole 123.

The position of the upper fixing bracket 200 can be fixed in the upper side of the battery module 100a, 100b by the first upper holder 204a, the second upper holder 204b, the first upper mounter 206a, and the second upper mounter 206b. That is, due to the above structure, the upper fixing bracket 200 can maintain the structure of the battery module 100a, 100b.

The upper fixing bracket 200 is fixed to the first frame 110 of each of the first battery module 100a and the second battery module 100b. Each of the first upper mounter 206a and the second upper mounter 206b of the upper fixing bracket 200 is fixed to the first fastening hole 123 formed in the first frame 110 of each of the first battery module 100a and the second battery module 100b.

The rear bender 208 may fix a top cover 230 described below. The rear bender 208 may be fixed to a rear wall 234 of the top cover 230. The rear bender 208 may limit the rear movement of the top cover 230. Accordingly, it is possible to facilitate fastening of the top cover 230 and the upper fixing bracket 200.

The lower fixing bracket 210 is disposed in the lower side of the battery module 100a, 100b. The lower fixing bracket 210 includes a lower board 212 that covers at least a portion of the lower portion of the battery module 100a, 100b, a first lower holder 214a which is bent upward from the front end of the lower board 212 and disposed in contact with the front portion of the battery module 100a, 100b, a second lower holder 214b which is bent upward from the rear end of the lower board 212 and disposed in contact with the rear portion of the battery module 100a, 100b, a first lower mounter 216a which is bent upward from one side end of the lower board 212 and coupled to one side of the battery module 100a, 100b, and a second lower mounter 216b which is bent upward from the other side end of the lower board 212 and coupled to the other side of the battery module 100.

Each of the first lower mounter 216a and the second lower mounter 216b is disposed to surround the front and rear of the battery module 100a, 100b. Accordingly, the first lower mounter 216a and the second lower mounter 216b may maintain the state in which the first battery module 100a and the second battery module 100b are coupled.

A pair of first lower mounters 216a spaced apart in the front-rear direction are disposed in one side end of the lower board 212. A pair of second lower mounters 216b spaced apart in the front-rear direction are disposed in the other side end of the lower board 212.

The pair of first lower mounters 216a are coupled to the first fastening hole 123 formed in the first battery module 100a and the second battery module 100b. In each of the pair of first lower mounters 216a, a first lower mounter hole 216ah is formed in a position corresponding to the first fastening hole 123. Similarly, the pair of second lower mounters 216b are coupled to the first fastening hole 123 formed in the first battery module 100a and the second battery module 100b, and a second lower mounter hole 216bh is formed in a position corresponding to the first fastening hole 123.

The lower fixing bracket 210 is fixed to the first frame 110 of each of the first battery module 100a and the second battery module 100b. Each of the first lower mounter 216a and the second lower mounter 216b of the lower fixing bracket 210 is fixed to the first fastening hole 123 formed in the first frame 110 of each of the first battery module 100a and the second battery module 100b.

The battery pack circuit substrate 220 may be fixedly disposed in the upper side of the upper fixing bracket 200. The battery pack circuit substrate 220 is connected to the sensing substrate 190, the bus bar, or a thermistor 224 described below to receive information of a plurality of battery cells 101 disposed inside the battery pack 10. The battery pack circuit substrate 220 may transmit information of the plurality of battery cells 101 to the main circuit substrate 34a described below.

The battery pack circuit substrate 220 may be spaced apart from the upper fixing bracket 200 upward. A plurality of spacers 222 are disposed, between the battery pack circuit substrate 220 and the upper fixing bracket 200, to space the battery pack circuit substrate 220 upward from the upper fixing bracket 200. The plurality of spacers 222 may be disposed in an edge portion of the battery pack circuit substrate 220.

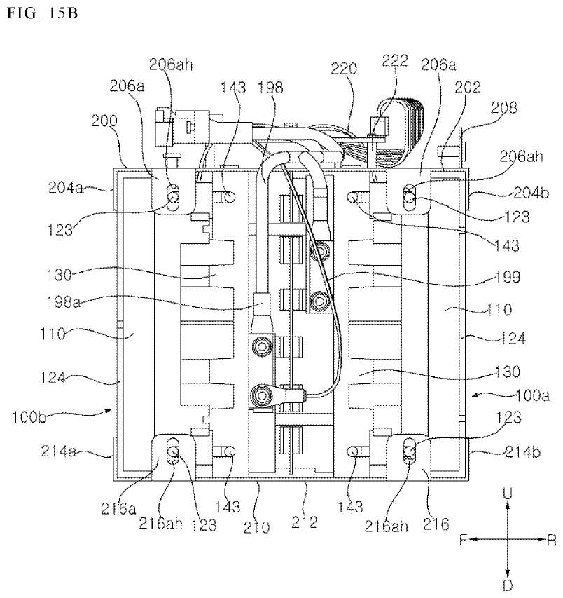

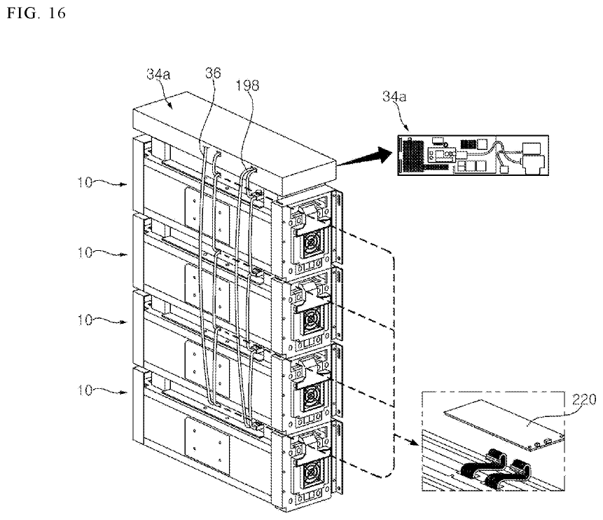

FIG. 16 is a diagram for explaining a connection between the battery pack and the battery management system according to an embodiment of the present disclosure.

Referring to FIG. 16, the battery 35 that stores received electrical energy in a DC form or outputs the stored electrical energy may include a plurality of battery packs 10. Each battery pack 10 includes a plurality of battery cells 101 connected in series and parallel.

The battery pack 10 may include battery modules 100a and 100b in which the plurality of battery cells 101 are connected in series and in parallel, and the battery modules 100a and 100b may be electrically connected to each other.

The battery cells 101 may be connected in series to increase voltage, and may be connected in parallel to increase capacity. In order to increase both the voltage and the capacity, the battery cells 101 may be connected in series and parallel.

Meanwhile, the battery management system 34 for monitoring the state information of the battery 35 includes a battery pack circuit boards 220 which are disposed in each of the plurality of battery packs 10, and obtain state information of the plurality of battery cells 101 included in each battery pack 10, and a main circuit board 34a which is connected to the battery pack circuit boards 220 by a communication line 36, and receives the state information obtained from each battery pack 10 from the battery pack circuit boards 220.

The energy storage system 1 according to an embodiment of the present disclosure includes the battery 35 that stores the received electrical energy in the form of direct current, or outputs the stored electrical energy, the power conditioning system 32 for converting an electrical characteristic so as to charge or discharge the battery 35, and the battery management system 34 for monitoring the state information of the battery 35. The battery 35 includes a plurality of battery packs 10 respectively including a plurality of battery cells 101, and the battery management system 34 includes battery pack circuit boards 220 which is disposed in each of the plurality of battery packs 10 and obtains state information of a plurality of battery cells 101 included in each battery pack 10, and a main circuit board 34a which is connected to the battery pack circuit boards 220 by a communication line and receives state information obtained from each battery pack 10 from the battery pack circuit boards 220.

According to an embodiment of the present disclosure, by separately designing the control circuit 34a including a configuration for managing the battery 35 (particularly a configuration for safety control) from the battery cell sensing circuit 220, it is possible to perform the main function of the battery management system 34 and protect the control circuit 34a that manages the plurality of battery packs 10.

In the battery management system 34, a circuit composed of main components including the microcomputer unit 1780 among circuits for safety control may be separately configured. For example, when four battery packs 10 are configured to be connected, the battery management system 34 may be designed with one control circuit unit block 34a including the microcomputer unit 1780, and four battery unit blocks 220.

When the battery pack 10 is short-circuited due to an internal problem, the battery unit block 220 directly connected to the battery cell 101 may be damaged. However, the safety control circuit 34a is designed independently and can be protected without damage.

In addition, since the control circuit 34a and the battery cell sensing circuit 220 are separately configured, each circuit board 34a, 220 can be made smaller.

Meanwhile, the state information transmitted from the battery pack circuit boards 220 to the main circuit board 34a may include at least one of current, voltage, and temperature data. In addition, some of the state information may be measured by a sensor mounted in the main circuit board 34a.

The battery pack circuit boards 220 are sensing and interface boards for voltage, current, and temperature of the battery cells 101. In the battery pack circuit boards 220, a component for obtaining voltage, current, and temperature data of a plurality of battery cells 101 and an interface component for transmitting the obtained data to the main circuit board 34a may be mounted. The voltage, current, and temperature data of the plurality of battery cells 101 may be directly obtained from a sensor mounted in the battery pack circuit boards 220, or may be transmitted to the battery pack circuit substrates 220 from a sensor disposed in the battery cell 101 side.

The plurality of battery packs 10 are connected in series by the power line 198. The power line 198 is connected to the main circuit board 34a. That is, the plurality of battery packs 10 and the main circuit board 34a are connected by the power line 198, and the voltages of the plurality of battery packs 10 are combined and applied to the main circuit board 34a. For example, a plurality of 4 kWh battery packs may be connected in series and disposed inside the casing 12. Two 4 kWh battery packs 10 may be connected to implement a combination 8 kWh, three 4 kWh battery packs 10 may be connected to implement a combination 12 kWh, and four 4 kWh battery packs 10 may be connected to implement a combination 16 kWh.

Two battery modules 100a and 100b may be combined to form a battery module assembly 100, and the battery pack circuit board 220 may be disposed in an upper portion of the battery module assembly 100.

Meanwhile, the power conditioning system 32 for converting electrical characteristics for charging or discharging the battery 35 may be disposed in the upper side of the main circuit board 34a.

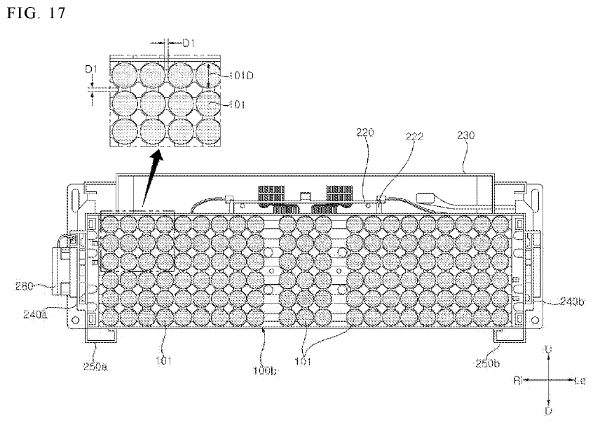

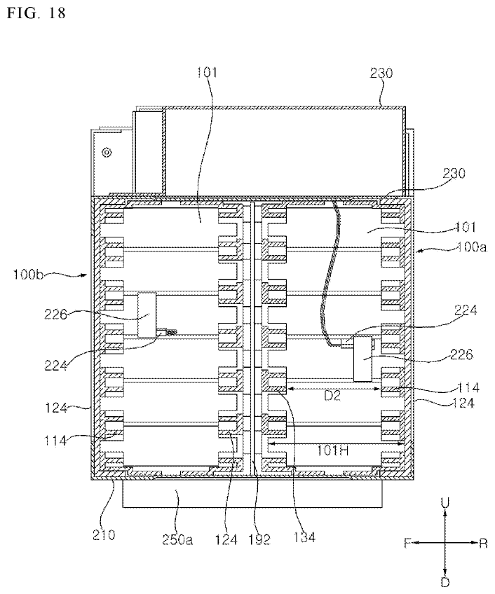

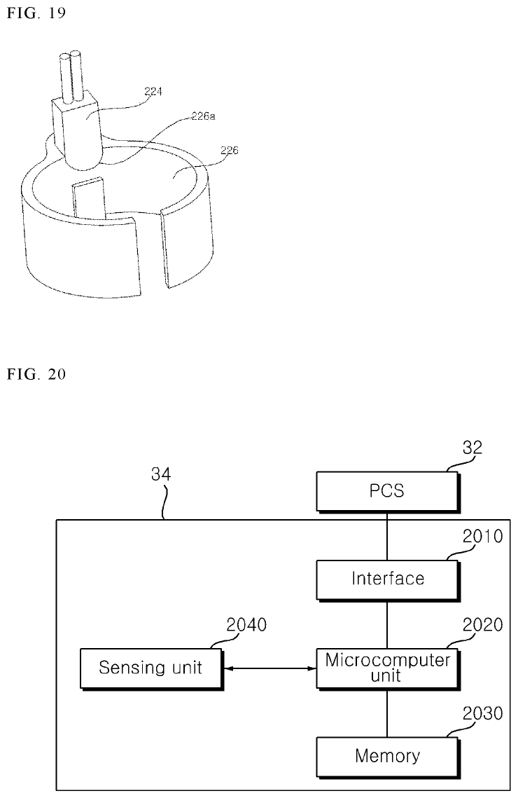

FIG. 17 is a cross-sectional view of a battery pack according to an embodiment of the present disclosure, FIG. 18 is a cross-sectional view for explaining a disposition of battery cells inside a battery pack, FIG. 19 is a perspective view of a thermistor according to an embodiment of the present disclosure.

Hereinafter, a structure for heat dissipation of the battery pack will be described with reference to FIGS. 17 to 19.

Referring to FIG. 17, a plurality of battery cells 101 are spaced apart from each other in four directions which are perpendicular to each other. Referring to FIG. 17, a plurality of battery cells 101 are spaced apart from each other in up, down, left, and right directions.

The disposition of the plurality of battery cells 101 is fixed by the second fixing protrusion 134 of the second frame 130 and the first fixing protrusion 114 of the first frame 110.

Referring to FIG. 17, a distance D1 between the battery cell 101 and other adjacently disposed battery cell 101 may be 0.1 to 0.2 times a diameter 101D of the battery cell 101. An air flow may be formed between the spacing of the plurality of battery cells 101 by the operation of the cooling fan 280.

Referring to FIG. 18, a distance D2 between the second fixing protrusion 134 of the second frame 130 and the first fixing protrusion 114 of the first frame 110 may be 0.5 to 0.9 times the height 101H of the battery cell 101. Accordingly, the area in which the outer circumference of the battery cell 101 is in contact with the flowing air can be maximized.

The cooling fan 280 operates to discharge the air inside the battery module 100a, 100b to the outside. Accordingly, when the cooling fan 280 operates, external air is supplied to the battery module 100a, 100b through the cooling hole 242a of the side cover 240 where the cooling fan 280 is not disposed. In addition, when the cooling fan 280 operates, the air inside the battery module 100a, 100b may be discharged to the outside through the cooling hole 242a of the side cover 240 in which the cooling fan 280 is disposed.

Referring to FIG. 17, the cover plate 242 of each of the pair of side covers 240a and 240b is disposed to be spaced apart from one side end of the battery module 100a, 100b. The size of the cooling hole 242a is formed smaller than the size of one side surface of the battery module 100a, 100b. Accordingly, the cover plate 242 having the cooling hole 242a formed therein is spaced apart from one side end of the battery module 100a, 100b so that the air introduced through the cooling hole 242a flows to each of the plurality of battery cells 101.

The heat dissipation plate 124 is disposed in a lower portion of each of the plurality of battery cells 101. The heat dissipation plate 124 may be formed of an aluminum material to dissipate heat generated in the battery cell 101 to the outside. Each of the plurality of battery cells 101 may be adhered to the heat dissipation plate 124 through a conductive adhesive solution.

The conductive adhesive solution, which is a bonding solution containing alumina, fixes the heat dissipation plate 124 disposed in a lower portion of the battery cell 101 and transfers heat generated from the battery cell 101 to the heat dissipation plate 124.

In some of the plurality of battery cells 101, a thermistor 224 for measuring the temperature of the battery cell 101, and a mounting ring 226 for fixing the disposition of the thermistor 224 to the outer circumference of the battery cell 101 are disposed. The thermistor 224 may be disposed in the battery cell 101 disposed in a portion where mainly temperature is increased among the plurality of battery cells 101.

The mounting ring 226 has an open ring shape at one side, and forms a mounting groove 226a in which the thermistor 224 is mounted at one side that is not opened. The mounting ring 226 is mounted in the outer circumference of the battery cell 101 to bring the thermistor 224 into contact with the outer circumferential surface of the battery cell 101.

The thermistor 224 is connected to the battery pack circuit substrate 220 through the signal line 199. The thermistor 224 may transmit temperature information detected by the battery cell 101 to the battery pack circuit substrate 220. The battery pack 10 may adjust the rotation speed of the cooling fan 280 based on the temperature information detected from the thermistor 224.

The heat dissipation plate 124 may be disposed to contact one side of the casing 12 described below. The casing 12 is configured to accommodate at least one battery pack 10. Accordingly, the heat dissipation plate 124 may transfer the heat received from the battery cell 101 to the casing 12.

When the temperature of the battery 35 rises to a high temperature and is continuously used, the battery life is reduced. In addition, when the temperature of the battery 35 is used at a low temperature, internal resistance is increased, so that efficiency is lowered and high output is difficult.

Accordingly, according to an embodiment of the present disclosure, charging/discharging of the battery may be controlled based on the temperature of the battery cell 101 sensed by the thermistor 224.

FIG. 20 is a block diagram of an energy storage system according to an embodiment of the present disclosure, and illustrates an internal block of the battery management system 34.

As described above, the energy storage system 1 according to an embodiment of the present disclosure includes a battery 35 and a battery management system 34 for controlling the battery 35.

Referring to FIG. 20, the battery management system 34 according to an embodiment of the present disclosure includes a sensing unit 2040 including a sensor for measuring the voltage, current, and temperature of the battery 35, a memory 2030 that stores data necessary for the operation of the battery management system 34, and a microcomputer unit 2020 that controls the overall operation of the battery management system 34.

In addition, the battery management system 34 may further include an interface 2010, and communicate with a power conditioning system 32 through the interface 2010. For example, the interface 2010 may communicate with the power conditioning system 32 in a CAN communication method.

The sensing unit 2040 may include a plurality of sensors that measure voltage, current, and temperature of the battery 35. The sensing unit 2040 may include at least one voltage sensor, at least one current sensor, and at least one temperature sensor. For example, the sensor for measuring the temperature of the battery 35 may be a thermistor 224 disposed in the outer periphery of at least one of the plurality of battery cells 101. In addition, the temperature of the battery 35 may be based on at least one of temperature data sensed by the thermistor 224. For example, the temperature of the battery 35 may be an average value or a maximum value of temperature data sensed by the thermistor 224.

Meanwhile, as described with reference to FIG. 16, the battery management system 34 may include battery pack circuit boards 220 which is disposed in each of the plurality of battery packs 10 and obtains state information of a plurality of battery cells 101 contained in each battery pack 10, and a main circuit board 34a which is connected to the battery pack circuit boards 220 by a communication line, and receives state information obtained by each battery pack 10 from the battery pack circuit boards 220. Here, the microcomputer unit 2120 and the memory 2130 may be mounted in the main circuit board 34a. The plurality of battery packs 10 may be connected in series by a power line 198, and the power line 198 may be connected to the main circuit board 34a. Accordingly, when the battery pack 10 is short-circuited due to an internal problem, even if the battery pack circuit boards 220 directly connected to the battery cell 101 are damaged, the microcomputer unit 2120 and the memory 2130 of the independently designed main circuit board 34a may be protected without damage.

Meanwhile, the thermistor 224 and the battery pack circuit board 220 contained in each of the plurality of battery packs 10 may be connected by wire.

The microcomputer unit 2120 may control the battery 35 and the battery management system 34 using information obtained through the sensing unit 2040. In addition, the microcomputer unit 2120 may estimate or update a major factor such as SOC and SOH by using information obtained through the sensing unit 2040.

In some embodiment, the battery management system 34 may include a calculating unit for estimating major factors such as SOC and SOH under the control of the microcomputer 2120. For example, the battery management system 34 may further include an SOC calculating unit (not shown) for calculating SOC and/or an SOH calculating unit (not shown) for calculating SOH. The SOC calculating unit and/or the SOH calculating unit may estimate major factors such as SOC and SOH under the control of the microcomputer 2120. Hereinafter, an embodiment in which the microcomputer unit 2120 directly calculates major factors such as SOC and SOH will be described.

Meanwhile, the microcomputer unit 2120 may store the estimated or updated main factor in the memory 2030.

In the memory 2030, at least a portion of the state of charge (SOC) of the battery, the state of health (SOH) of the battery, a charge/discharge cycle count that is increased according to execution of charge/discharge cycle, a under voltage protection level which is a reference value of under voltage protection that protects against discharge below a certain voltage, and a power table including C-rate values corresponding to the temperature of the battery and the SOC of the battery may be stored.

The charge/discharge cycle count is an index for accumulating and storing the number of charge/discharge cycle executions. For example, the microcomputer unit 2020 may increase the charge/discharge cycle count by 1 whenever a charging or discharging charge/discharge cycle is executed. Alternatively, the microcomputer unit 2020 may increase the charge/discharge cycle count by 1 whenever a discharge charge/discharge cycle is executed, thereby counting the number of times the energy charged in the battery 35 is used.

The energy storage system 1 has a under voltage protection function for protecting from being discharged at a certain voltage or lower. In this case, the certain voltage may be referred to as an under voltage protection level. That is, the under voltage protection level is a reference value at which discharging is blocked, and the microcomputer 2020 may stop discharging when the battery voltage detected by the sensing unit 2040 drops to the under voltage protection level.

Meanwhile, the under voltage protection level may include a fault level 1 and a fault level 2. When the battery voltage drops to the fault level 1, discharging is stopped, but when the battery voltage is recovered to a certain level or more, the discharging stop may also be released. If the battery voltage drops to the fault Level 2, which is lower than the fault Level 1, the battery is unusable.

The microcomputer unit 2020 may control a C-rate based on the power table. The C-rate is called a charge rate, a discharge rate, a charge/discharge rate, or the like, is a unit for setting a current value during charging/discharging, and may be calculated according to Equation of C-rate(A)=charge-discharge current A/rated capacity of battery. The power table may include C-rate values corresponding to the temperature of the battery 35 and the SOC of the battery 35.

The microcomputer unit 2120 may calculate the SOC of the battery 35, and control charging and discharging of the battery based on the calculated state of charge, the temperature of the battery 35, and the power table.

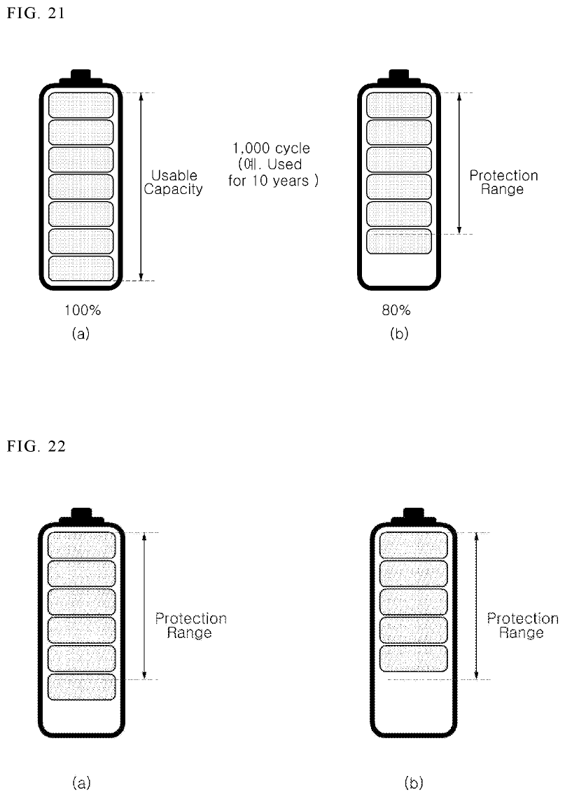

FIGS. 21 and 22 are diagrams for explaining a battery state according to a lapse of use time.

FIG. 21 is a diagram illustrating a usable capacity and a protection range of a battery according to the lapse of use time.

FIG. 21A illustrates an initial state, and when the battery is fully charged, 100% of the capacity can be used. For example, when 1,000 charge/discharge cycles are executed as the battery has been used for 10 years, the battery capacity may decrease by 80% fh as shown in FIG. 21B. Meanwhile, the protection range may be fixed at a level of 75% of the capacity.

FIG. 22A illustrates a case of usage in a general use environment. For example, 1,000 charge/discharge cycles may be executed by using the battery for 10 years in a normal use environment. In this case, the battery has sufficient capacity to satisfy the protection range.

FIG. 22B illustrates a case used in the worst-case environment. For example, a battery can run 2,000 charge/discharge cycles using 10 years of worst-case conditions. In this case, the battery may not have sufficient capacity to satisfy the protection range. Depending on the operating environment of the battery, the battery voltage may drop to the under voltage protection level or lower, and thus discharge may be stopped, or the battery can no longer be used.

Conventionally, the under voltage protection level is fixed. Due to the increase of the charge/discharge cycle time of the battery in a short time in the worst use environment, if the voltage drops to the fixed under voltage protection level or lower, the battery cannot be used.

According to an embodiment of the present disclosure, it is possible to increase the battery life and secure the safety of the battery by varying the main control factor.

In addition, according to an embodiment of the present disclosure, even when the battery capacity varies according to the usage environment, it is possible to prevent the sudden stop of operation of a product used for a long time in a specific usage environment.

According to an embodiment of the present disclosure, the memory 2030 may store a charge/discharge cycle count that is increased according to charge/discharge cycle execution, and a under voltage protection level which is a reference value of under voltage protection that protects from being discharged at a certain voltage or lower, and the microcomputer 2020 may change the under voltage protection level when the charge/discharge cycle count reaches a reference number of times. For example, the microcomputer unit 2020 may increase the under voltage protection level when the charge/discharge cycle count reaches a reference number of times.

In addition, the microcomputer unit 2020 may store the changed under voltage protection level in the memory 2030.

Accordingly, it is possible to perform a sufficient under voltage protection operation for a battery that is frequently used, thereby securing stability. In addition, since the stability of the frequently used battery is secured, the battery can be safely used for a longer period of time.

According to an embodiment of the present disclosure, when the charge/discharge cycle count reaches the reference number of times, the microcomputer unit 2020 may decrease the SOH (State Of Health) of the battery 35 and store it in the memory 2030, and may increase the under voltage protection level to correspond to the decrease in the SOH.

That is, by tracking the SOH according to the increase in the number of uses, the under voltage protection level can be varied, and the battery life can be extended while securing the safety of the product through an operation stop prevention algorithm. For example, when the charge/discharge cycle count is 4,000 charge/discharge cycles, if the SOH is 70%, the microcomputer 2020 may decrease the SOH to 60% when the charge/discharge cycle count is 8,000 charge/discharge cycles. In addition, the microcomputer unit 2020 may vary the under voltage protection level in response to the decrease in the SOH.

In addition, the microcomputer unit 2020 may increase the state of charge (SOC) of the battery and store in the memory 2030 so as to correspond to the decrease in the SOH.

The battery state of charge (SOC) is referred to as the charge amount, the remaining capacity, or the charging status, and indicates a capacity currently stored in the battery compared to a usable capacity in the battery. Here, the usable capacity in the battery may be the battery SOH as a total capacity.

SOC is usually expressed as a percentage, and is estimated by various methods such as a voltage measurement method and a coulomb counting method. The coulomb counting method calculates the SOC by measuring and integrating the output current over the entire operating time. In the voltage measurement method, the open circuit voltage (OCV) of the battery is measured, and the SOC of the battery is estimated by using an OCV table of the battery.

Meanwhile, the increase amount of the SOC may be proportional to the increase amount of the under voltage protection level. That is, as the SOC increases, the under voltage protection level may also increase significantly.

The microcomputer unit 2020 may update a power table including C-rate values corresponding to the temperature of the battery 35 and the SOC of the battery 35, and store in the memory 2030.

The microcomputer unit 2020 may decrease the C-rate values to prevent the battery 35 whose total capacity is decreased due to use from aging faster with a high C-rate.

In addition, the microcomputer unit 2020 may increase SOC values contained in the power table. That is, it is possible to generally shift the power table by increasing the SOC values. Accordingly, it is possible to lower the C-rate with the same SOC.

Meanwhile, the charge/discharge cycle count may be increased based on the number of discharges.

According to an embodiment of the present disclosure, when the charge/discharge cycle count reaches a reference number of times, the microcomputer unit 2020 may decrease the C-rate values in the power table containing C-rate values corresponding to the temperature of the battery 35 and the SOC of the battery 35, and may stored in the memory 2030.

Meanwhile, the microcomputer unit 2020 may read the charge/discharge cycle count from the memory 2030 when power is applied to the energy storage system 1 product.

Meanwhile, when the charge/discharge cycle is executed, the microcomputer unit 2020 may increase the charge/discharge cycle count, and store in the memory 2030.

The microcomputer 2020 may store a current charge/discharge cycle count in the memory 2030, when the power is turned off. In addition, the microcomputer unit 2020 may store the changed SOH, SOC, and power table in the memory 2030, when the power is turned off.

According to an embodiment of the present disclosure, a plurality of reference number of times are set, and the microcomputer unit 2020 may increase the under voltage protection level, whenever the charge/discharge cycle count reaches each reference number of times. For example, when the charge/discharge cycle count reaches a first reference number of times, the under voltage protection level may be increased, and then, when the charge/discharge cycle count reaches a second reference number of times, the under voltage protection level may be increased. In addition, whenever the charge/discharge cycle count reaches each reference number of times, the SOH, SOC, and power table can also be changed.

According to an embodiment of the present disclosure, a charge/discharge cycle count that is increased according to the execution of the charge/discharge cycle, and a power table containing C-rate values corresponding to the temperature of the battery and the SOC of the battery are stored in the memory 2030, and when the charge/discharge cycle count reaches a reference number of times, the microcomputer unit 2020 may change the C-rate values and store in the memory 203. For example, when the charge/discharge cycle count reaches a reference number of times, the microcomputer unit 2020 may decrease the C-rate values and store in the memory 2030.

When charging/discharging a battery with a high C-Rate, the battery life may be shortened due to rapid aging. The fixed C-Rate promotes rapid aging when the charge/discharge cycle time elapses. Depending on the setting, the charge/discharge cycle time may be managed based on the number of times, and in this case, the charge/discharge cycle time may be the same as the charge/discharge cycle count.

As the charge/discharge cycle time elapses, the battery capacity value changes. Accordingly, it is possible to extend the battery life by varying the C-Rate in response to a change in capacity.

Meanwhile, when the charge/discharge cycle count reaches a reference number of times, the microcomputer unit 2020 may decrease the state of health (SOH) of the battery 35 and store in the memory 2030.

The microcomputer unit 2020 may increase the state of charge (SOC) of the battery to correspond to the decrease in the SOH and store in the memory 2030.

The microcomputer unit 2020 may increase the under voltage protection level, when the charge/discharge cycle count reaches a reference number of times.

In addition, when the charge/discharge cycle count reaches a reference number of times, the microcomputer 2020 may decrease the state of health (SOH) of the battery and store in the memory 2030, and may increase the under voltage protection level to correspond to the decrease in the SOH. The increased under voltage protection level may be stored in the memory 2030.

According to an embodiment of the present disclosure, the memory 2030 may store a state of charge (SOC) of the battery 35, a state of health (SOH) of the battery 35, a charge/discharge cycle count that is increased according to the charge/discharge cycle execution, a under voltage protection level which is a reference value of under voltage protection that protects against discharge at a certain voltage or lower, a power table including C-rate values corresponding to the temperature of the battery 35 and the SOC of the battery 35.

As described above, when the charge/discharge cycle count reaches a reference number of times, the microcomputer unit 2020 may change data stored in the memory 2030.

For example, the microcomputer unit 2020 may decrease the SOH stored in the memory 2030, when the charge/discharge cycle count reaches a reference number of times.

In addition, the microcomputer unit 2020 may update the SOC of the battery, in response to the decrease in the SOH. For example, the microcomputer unit 2020 may increase the SOC of the battery, in response to the decrease in the SOH.

In addition, the microcomputer unit 2020 may update the under voltage protection level, in response to a change in the SOH and/or the SOC.

In addition, the microcomputer unit 2020 may update the power table, in response to a change in the SOH and/or the SOC.

According to an embodiment of the present disclosure, the SOC may be varied, based on a change amount of state of health (SOH) of battery. In addition, the C-Rate and the under voltage protection (UVP) may be varied, based on a change amount of state of health (SOH) of battery. Accordingly, it is possible to extend the lifespan of the battery while ensuring reliability.

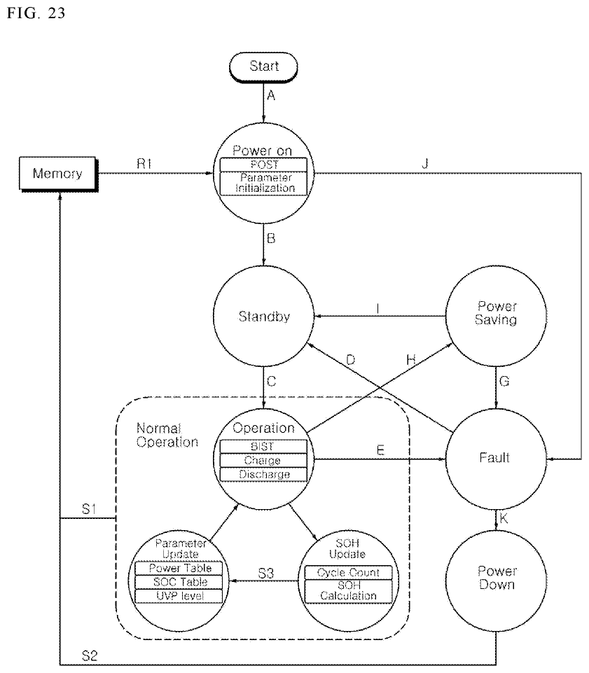

FIG. 23 is a state transition diagram of an energy storage system according to an embodiment of the present disclosure.

When a user presses the power button, power may be applied (state transition A).

When battery power is applied, the microcomputer 2020 may read a charge/discharge cycle count from the memory 2030 (state transition R1).

Meanwhile, when power is applied to the battery, a power-on self test (POST) is first performed, and if there is no abnormality in the POST process, various parameters are set, and the battery management system 34 may enter a standby state (state transition B).

Thereafter, the battery management system 34 enters a normal operation state (state transition C).

Meanwhile, in the normal operating state, when there is no response of the power conditioning system 32 or the power conditioning system 32 is in a sleep mode, the battery management system 34 may enter a power saving mode (state transition H).

Meanwhile, when a fault condition, such as reaching the under voltage protection level, is satisfied, it is switched to a fault state (state transitions E, G), and various parameters may be updated (state transition S1). For example, the microcomputer unit 2020 may update at least one of the power table, the SOC, and the under voltage protection level. In addition, the microcomputer 2020 may update the SOH and the charge/discharge cycle count.

Meanwhile, when the fault condition is resolved, it may be switched to the standby state (state transition D).

Meanwhile, the power may be turned off according to the type and condition of the fault (state transition K). For example, the under voltage protection level may include fault level 1 and fault level 2. When the battery voltage drops to the fault level 1, discharging is stopped, but when the battery voltage is recovered to a certain level or more, the discharging stop may also be released. When the battery voltage drops to fault level 2 which is lower than fault level 1, the power may be turned off.

Meanwhile, when the power is turned off (state transition K), the microcomputer 2020 may store parameter values up to now in the memory 2030 (state transition S2).

Meanwhile, in the normal operation state, the battery management system 34 performs a built-in self-test (BIST), and when a fault is detected, the microcomputer 2020 may store the parameter values up to now in the memory 2030 (state transition S1).

Meanwhile, when the charge/discharge cycle count is changed (increased by one time), the microcomputer 2020 may store the increased charge/discharge cycle count in the memory 2030 (state transition S3). In addition, the microcomputer 2020 may calculate the SOH again and update the SOH (state transition S3). More preferably, when the charge/discharge cycle count reaches the reference number of times, the microcomputer unit 2020 may calculate the SOH again and update the SOH (state transition S3).

Meanwhile, the increase of the charge/discharge cycle count may be calculated based on discharge.

Meanwhile, parameter update may be performed based on the update of the SOH.

Hereinafter, an update process of various parameters will be described with reference to the drawings.

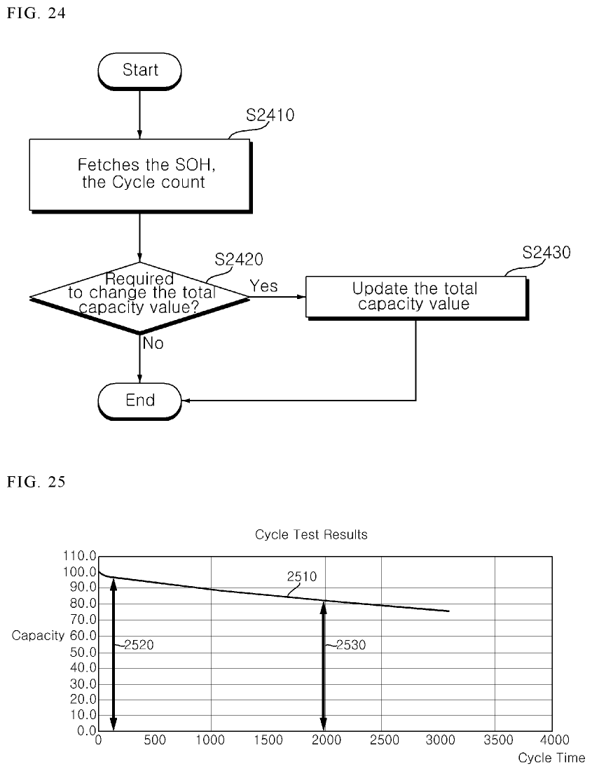

FIG. 24 is a flowchart illustrating a method of operating an energy storage system according to an embodiment of the present disclosure, and illustrates a SOH update process.

Referring to FIG. 24, the microcomputer 2020 fetches the SOH and the charge/discharge cycle count from the memory 2030 (S2410).

When it is required to change the total capacity value (state of health: SOH) (S2420), the microcomputer unit 2020 may update the total capacity value SOH (S2430).

For example, when the charge/discharge cycle count is increased by one time, it may be stored in the memory 2030 and used to change the total capacity value SOH. The microcomputer 2020 may determine that a change of the total capacity value SOH is required, when the charge/discharge cycle count reaches a preset reference number of times.

FIG. 25 is a graph illustrating changes in capacity SOH according to the lapse of battery use time, and in this case, the capacity may be a total capacity SOH.

FIG. 25 illustrates the capacity value SOH change 2510 according to the lapse of charge/discharge cycle, the initial capacity value SOH 2520 of the battery, and the capacity value SOH 2530 after 2,000 charge/discharge cycle.

Referring to FIG. 25, at 1000 charge/discharge cycle, the total capacity becomes 90%. When the charge/discharge cycle count reaches a preset reference number of times, the microcomputer 2020 may change the total capacity value SOH. For example, whenever the charge/discharge cycle count reaches a preset reference number of times such as 300 charge/discharge cycle, 600 charge/discharge cycle, and 900 charge/discharge cycle, the microcomputer 2020 may change the total capacity value SOH and store in the memory 2030.

In some embodiment, the microcomputer 2020 may change the C-Rate. For example, if the initial 1 C (C-Rate) is 4060 mA, when the total capacity SOH reaches 90%, the C-Rate can be changed as follows.

1 C=4060 mA*90%=3654 mA

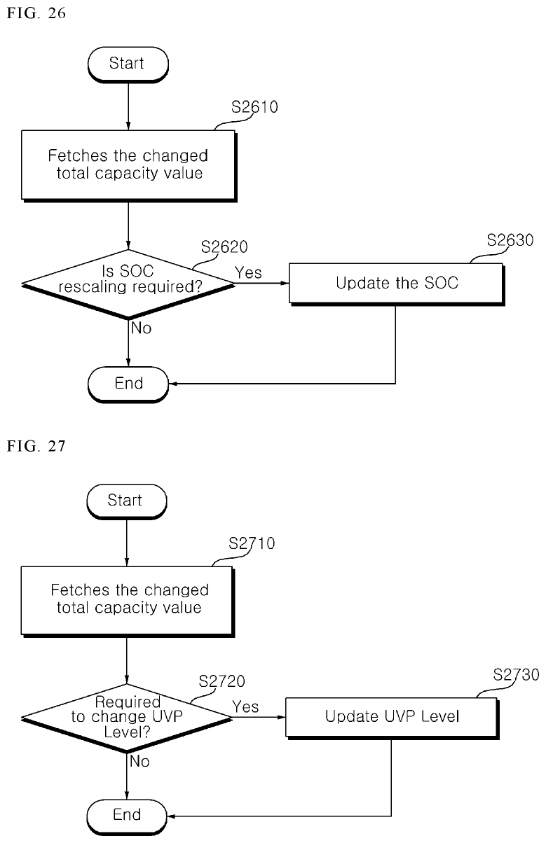

FIG. 26 is a flowchart illustrating a method of operating an energy storage system according to an embodiment of the present disclosure, and illustrates an SOC (state of charge) rescaling process.

Referring to FIG. 26, the microcomputer 2020 fetches the changed total capacity value SOH (state of health) from the memory 2030 (S2610).

When SOC rescaling is required (S2620), the microcomputer 2020 may update the SOC (S2630). For example, when the total capacity value SOH is changed, it may be determined that rescaling of the SOC is required.

The SOC may be a value expressed as a percentage of the current remaining capacity compared to the total capacity SOH as follows.

SOC=(Current remaining capacity/Total capacity SOH)*100

Even if the current remaining capacity is the same, when the total capacity SOH is changed, the SOC value changes as shown in the above equation. Accordingly, if the SOH (total capacity) value is changed according to the increase in the charge/discharge cycle count, the microcomputer 2020 may rescale and store the SOC.

FIG. 27 is a flowchart illustrating a method of operating an energy storage system according to an embodiment of the present disclosure, and illustrates a under voltage protection level updating process.

Referring to FIG. 27, the microcomputer 2020 fetches the changed total capacity value SOH from the memory 2030 (S2710).

When it is required to change the under voltage protection level (UVP) (S2720), the microcomputer unit 2020 may update the under voltage protection level (S2730). For example, when the total capacitance value SOH is changed, it may be determined that a change in the under voltage protection level is required.

In the Under voltage protection, when the battery voltage is equal to or lower than the under voltage protection level during discharging, the discharging is stopped, thereby preventing damage to the battery cell due to a low voltage.

For example, the initial under voltage protection level may be set to 3.15V. In this case, the protection function operates at 3.15V or less to turn off the relay, so that further discharging can be prevented. The under voltage protection level can be set based on SOC and SOH. For example, the 3.15V may be set based on SOC 4%.

Meanwhile, the microcomputer 2020 may gradually increase the under voltage protection level, in response to SOC rescaling according to the SOH change.

Meanwhile, the under voltage protection level can be increased limitedly. For example, if the maximum SOH (total capacity) is limited to 60% of the initial value, SOC 4% is 3.650V. In this case, the maximum Max value of the under voltage protection level may be set to 3.650V.

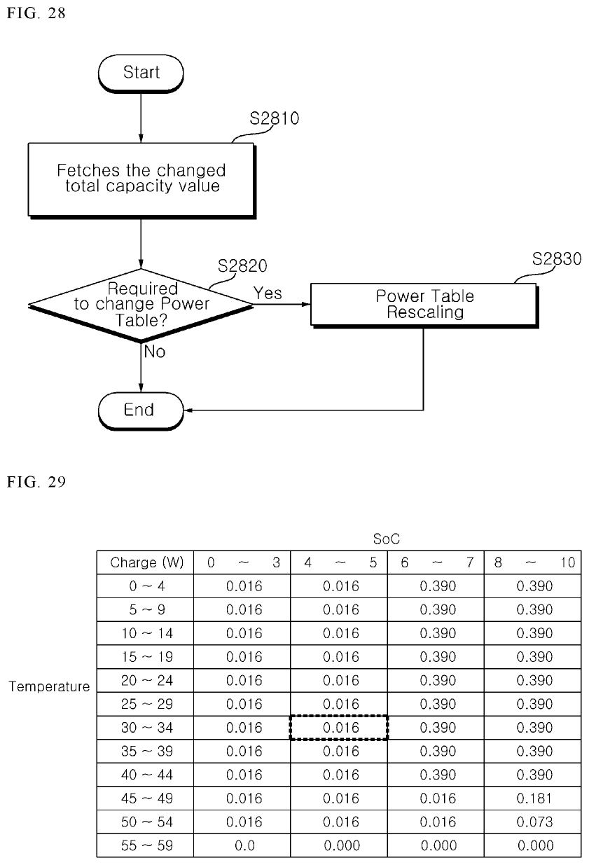

FIG. 28 is a flowchart illustrating a method of operating an energy storage system according to an embodiment of the present disclosure, and illustrates a power table rescaling process.

Referring to FIG. 28, the microcomputer 2020 fetches the changed total capacity value SOH from the memory 2030 (S2810).

When a power table rescaling is required (S2820), the microcomputer unit 2020 may update the power table (S2830). For example, when the total capacity value SOH is changed, it may be determined that rescaling of the power table is required.

The power table is a table including values for controlling a charging and discharging according to SOC and temperature, during charging and discharging of battery. The power table may include C-rate values corresponding to the temperature of the battery 35 and the SOC of the battery 35.

FIG. 29 is a diagram for explaining a power table according to an embodiment of the present disclosure, and illustrates a part of the power table.

In FIG. 29, the X-axis is SOC, the Y-axis is temperature, and the internal value is C-Rate. A cell indicated by a dotted line in FIG. 29 means that the battery is charged with a power of C-Rate 0.016 in a section of SOC 4 to 5% and in a section of temperature 30 to 34 degrees.

The power table update is performed due to SOH (capacity) change. The power table update may be performed in response to changes in SOC and C-Rate according to change in SOH (capacity).

According to an embodiment of the present disclosure, battery life may be extended by changing SOH and SOC and changing VP Level and/or C-Rate as a charge/discharge cycle is performed. Accordingly, the warranty cost according to the usage environment of the battery can also be decreased.

According to at least one of the embodiments of the present disclosure, the battery life can be extended by changing the main control factor according to the lapse of use time.

In addition, according to at least one of the embodiments of the present disclosure, the battery usage period can be extended while ensuring the stability of battery.

In addition, according to at least one of the embodiments of the present disclosure, data may be effectively managed.

While the present invention has been particularly shown and described with reference to exemplary embodiments thereof, it will be understood by those of ordinary skill in the art that various changes in form and detail may be made herein without departing from the spirit and scope of the present invention as defined by the following claims and such modifications and variations should not be understood individually from the technical idea or aspect of the present invention.

What is claimed is:

1. An energy storage system comprising:
a battery configured to store a received electrical energy in a form of direct current, and to output the stored electrical energy; and
a battery management system configured to control the battery,
wherein the battery management system comprises:
a sensing unit comprising a plurality of sensors for measuring voltage, current, and temperature of the battery;
a memory configured to store a charge/discharge cycle count that is increased according to execution of a charge/discharge cycle and a under voltage protection level which is a reference value of a under voltage protection that protects the battery from discharging at a certain voltage or lower; and
a microcomputer unit that increases the under voltage protection level, based on the charge/discharge cycle count reaching a reference number of times.

2. The energy storage system of claim 1, wherein based on the charge/discharge cycle count reaching the reference number of times, the microcomputer unit decreases a state of health (SOH) of the battery and stores the SOH in the memory, and increases the under voltage protection level to correspond to the decrease in the SOH.

3. The energy storage system of claim 2, wherein the microcomputer unit increases the state of charge (SOC) of the battery to correspond to the decrease in the SOH and stores the SOC in the memory.

4. The energy storage system of claim 3, wherein an amount of increase of the SOC is proportional to an amount of increase of the under voltage protection level.

5. The energy storage system of claim 4, wherein the microcomputer unit updates a power table including charging rate (C-rate) values corresponding to a temperature of the battery and the SOC of the battery and stores the updated power table in the memory.

6. The energy storage system of claim 5, wherein the microcomputer unit decreases the C-rate values.

7. The energy storage system of claim 5, wherein the microcomputer unit increases SOC values included in the power table.

8. The energy storage system of claim 1, wherein the charge/discharge cycle count is increased based on the number of times of discharge.

9. The energy storage system of claim 1, wherein based on the charge/discharge cycle count reaching the reference number of times, the microcomputer unit decreases C-rate values in a power table including the C-rate values corresponding to the temperature of the battery and a SOC of the battery and stores the decreased C-rate values in the memory.

10. The energy storage system of claim 1, wherein based on power being applied, the microcomputer unit reads the charge/discharge cycle count from the memory.

11. The energy storage system of claim 10, wherein based on the charge/discharge cycle being executed, the microcomputer unit increases the charge/discharge cycle count and stores the increased charge/discharge cycle count in the memory.

12. The energy storage system of claim 10, wherein based on the power being turned off, the microcomputer unit stores a current charge/discharge cycle count in the memory.

13. The energy storage system of claim 1, wherein a plurality of the reference number of times are set, and
the microcomputer unit increases the under voltage protection level, whenever the charge/discharge cycle count reaches each reference number of times.

14. An energy storage system comprising:
a battery configured to store a received electrical energy in a form of direct current, or to output the stored electrical energy; and
a battery management system configured to control the battery,
wherein the battery management system comprises:
a sensing unit comprising a plurality of sensors for measuring voltage, current, and temperature of the battery;
a memory configured to store a charge/discharge cycle count that is increased according to execution of charge/discharge cycle, and a power table including charging rate (C-rate) values corresponding to temperature of the battery and a state of charge (SOC) of the battery; and
a microcomputer unit configured to decrease the C-rate values and store the decreased C-rate values in the memory, based on the charge/discharge cycle count reaching a reference number of times.

15. The energy storage system of claim 14, wherein based on the charge/discharge cycle count reaching the reference number of times, the microcomputer unit decreases a state of health (SOH) of the battery and stores the SOH in the memory.

16. The energy storage system of claim 15, wherein the microcomputer unit increases the state of charge (SOC) of the battery to correspond to the decrease in the SOH and stores the SOC in the memory.

17. The energy storage system of claim 14, wherein based on the charge/discharge cycle count reaching a reference number of times, the microcomputer unit increases a under voltage protection level.

18. The energy storage system of claim 17, wherein based on the charge/discharge cycle count reaching the reference number of times,
the microcomputer unit decreases a state of health (SOH) of the battery and store in the memory, and increases the under voltage protection level to correspond to the decrease in the SOH.

19. An energy storage system comprising:
a battery configured to store a received electrical energy in a form of direct current, or to output the stored electrical energy; and
a battery management system configured to control the battery,
wherein the battery management system comprises:
a sensing unit comprising a plurality of sensors for measuring voltage, current, and temperature of the battery;
a memory configured to store a state of charge (SOC) of the battery, a state of health (SOH) of the battery, a charge/discharge cycle count that is increased according to execution of charge/discharge cycle, a under voltage protection level which is a reference value of a under voltage protection that protects from discharging at a certain voltage or lower, and a power table including charging rate (C-rate) values corresponding to temperature of the battery and the state of charge (SOC) of the battery; and
a microcomputer unit configured to decrease the state of charge (SOC) of the battery, based on the charge/discharge cycle count reaching a reference number of times.

20. The energy storage system of claim 19, wherein the microcomputer unit updates the SOC of the battery, the under voltage protection level, and the power table according to the decrease of the SOH.
